(19) United States
(12) Patent Application Publication
(10) Pub. No.: US 2026/0114127 A1
(43) Pub. Date: Apr. 23, 2026

(54) LIGHT-EMITTING STRUCTURE, ELECTRONIC APPARATUS HAVING THE SAME AND METHOD FOR PROVIDING THE SAME

(71) Applicant: Samsung Display Co., Ltd., Yongin-si (KR)

(72) Inventors: YOUNGMIN MOON, Yongin-si (KR); ARONG KIM, Yongin-si (KR); Samin LEE, Yongin-si (KR); WONJE CHO, Yongin-si (KR)

(21) Appl. No.: 19/243,788

(22) Filed: Jun. 20, 2025

(30) Foreign Application Priority Data
Oct. 18, 2024 (KR) 10-2024-0143328

(51) Int. Cl. H10K 59/122; H10K 59/12

(52) U.S. Cl. CPC H10K 59/122; H10K 59/1201

(57) ABSTRACT

An electronic apparatus includes a pixel defining layer in which an emission opening and a groove which is adjacent to the emission opening are defined, a light-emitting element including a first electrode facing a second electrode and a light-emitting pattern which is between the first and second electrodes and overlapping the emission opening, the light-emitting pattern including a side surface corresponding to the groove of the pixel defining layer, and an insulating pattern which overlaps the pixel defining layer with the light-emitting pattern therebetween, the insulating pattern extending along the light-emitting pattern and into the groove to cover the side surface of the light-emitting pattern.

This application claims priority to Korean Patent Application No. 10-2024-0143328, filed on Oct. 18, 2024, and all the benefits accruing therefrom under 35 U.S.C. § 119, the entire contents of which are hereby incorporated by reference.

### BACKGROUND

### (1) Field

The present disclosure herein relates to an electronic apparatus and a method for manufacturing (or providing) the same. More particularly, the present disclosure herein relates to an electronic apparatus with improved reliability.

### (2) Description of the Related Art

Display devices of an electronic device such as televisions, monitors, smartphones, and tablets which provide images such as a still image or a moving image like a video a user include a display panel for generating and/or displaying the image. Various display panels such as liquid crystal display panels, organic light-emitting display panels, electro wetting display panels, and electrophoretic display panels are being developed as the display panel.

The organic light-emitting display panel may include an anode, a cathode, and a light-emitting pattern. The light-emitting pattern may be separated for each light emission area of the display panel, and the cathode may provide a common voltage for each light emission area.

### SUMMARY

The present disclosure provides an electronic apparatus with improved reliability and a method for manufacturing (or providing) the same, in a display panel which provides a light-emitting device without using a metal mask.

An embodiment of the invention provides an electronic apparatus including: a base layer, a pixel defining layer which is disposed on the base layer and in which a emission opening is defined, a light-emitting element including: a first electrode which is disposed on the base layer and of which at least a portion is exposed by the emission opening, a second electrode disposed on the first electrode, and a light-emitting pattern disposed between the first electrode and the second electrode to overlap the emission opening, and an insulating pattern disposed on the pixel defining layer, where the pixel defining layer includes: an inner surface configured to define a groove, and an outer surface configured to define the emission opening, where the insulating pattern is disposed in the groove to entirely cover a side surface of the light-emitting pattern.

In an embodiment, the electronic apparatus may further include a dummy pattern spaced apart from the light-emitting pattern and disposed in the groove, where the insulating pattern may be in contact with the dummy pattern.

In an embodiment, the dummy pattern may contain the same material as the light-emitting pattern.

In an embodiment, the second electrode may be disposed on the insulating pattern.

In an embodiment, the light-emitting pattern may be provided in plurality, where the plurality of light-emitting patterns may include a first light-emitting pattern configured to emit first-color light, a second light-emitting pattern configured to emit second-color light, which is different from the first-color light, and a third light-emitting pattern configured to emit third-color light, which is different from each of the first-color light and the second-color light, where the dummy pattern may be provided in plurality, where the plurality of dummy patterns may include a first dummy pattern containing the same material as the first light-emitting pattern, a second dummy pattern containing the same material as the second light-emitting pattern, and a third dummy pattern containing the same material as the third light-emitting pattern, where at least two of the first to third dummy patterns may be disposed in the groove.

In an embodiment, the at least two dummy patterns may be in contact with the one insulating pattern.

In an embodiment, the at least two dummy patterns may be spaced apart from each other.

In an embodiment, the insulating pattern may be in contact with the inner surface of the pixel defining layer configured to define the groove.

In an embodiment, the groove may have a reverse-tapered shape in cross-section.

In an embodiment, a portion of the pixel defining layer may be configured to define a tip portion which protrudes toward a center of the groove.

In an embodiment, the inner surface may include a curved portion in cross-section.

In an embodiment, the pixel defining layer may be a single layer.

In an embodiment, the pixel defining layer may include a first pixel defining layer, and a second pixel defining layer disposed on the first pixel defining layer, where a material of the first pixel defining layer may have an etching selectivity with respect to a material of the second pixel defining layer.

In an embodiment, the first pixel defining layer may include silicon nitride, and the second pixel defining layer may include silicon oxide.

In an embodiment of the invention, a method for manufacturing (or providing) an electronic apparatus includes forming (or providing) first electrodes on a base layer, forming a pixel defining layer, in which a plurality of emission openings which overlap at least a portion of each of the first electrodes, and a groove which is spaced apart from the emission openings and is defined between the emission openings, are defined, forming a first emission layer on the pixel defining layer to form first light-emitting patterns, which overlap first emission openings of the emission openings, and first dummy light-emitting patterns, which overlap the rest of the emission openings of the emission openings, forming a first insulating layer configured to cover a top surface and a side surface of each of the first light-emitting patterns, forming a first photoresist layer, which overlaps the first emission openings, on the first insulating layer, patterning the first insulating layer to form a first preliminary insulating pattern, removing at least a portion of the first dummy light-emitting pattern of the first emission layer to form a first light-emitting pattern, forming a second emission layer on the pixel defining layer to form second light-emitting patterns, which overlap second emission openings of the emission openings, and second dummy light-emitting patterns, which overlap the rest of the emission openings of the emission openings, on the first light-emitting pattern and the first preliminary insulating layer, forming a second insulating layer configured to cover a top surface of a side surface of each of second light-emitting patterns, forming a second photoresist layer, which overlaps the second emission openings, on the second insulating layer, patterning the second insulating layer to form a second preliminary insulating pattern, removing at least a portion of the second dummy light-emitting pattern of the second emission layer to form a second light-emitting pattern, forming a third photoresist layer on the first and second preliminary insulating patterns, patterning the first and second preliminary insulating patterns to form an insulating pattern, and forming a second electrode on the light-emitting pattern and the insulating pattern, where the first and second photoresist layer partially overlap the groove, and the third photoresist layer overlaps the groove and is spaced apart from the emission openings.

In an embodiment, the forming of the first emission layer further may include forming a first preliminary dummy pattern, which is separated from the first light-emitting patterns and the first dummy light-emitting patterns, in the groove, where the first preliminary dummy patterns may be patterned together during the patterning of the first insulating layer to form a first dummy pattern, where the forming of the second emission layer further may include forming a second preliminary dummy pattern, which is separated from the second light-emitting pattern and the second dummy light-emitting patterns, in the groove, where the second preliminary dummy pattern may be patterned together during the patterning of the second insulating layer to form a second dummy pattern.

In an embodiment, in the forming of the first insulating layer, the first insulating layer may be formed as an integrated layer which is in contact with the first light-emitting patterns and the first dummy light-emitting patterns.

In an embodiment, in the forming of the pixel defining layer may include forming a first pixel defining layer, forming a second pixel defining layer on the first pixel defining layer, and etching the first and second pixel defining layers using an etching gas to form the emission openings and the groove, where, in the forming of the groove, an etching rate of the etching gas with respect to the first pixel defining layer may be greater than that of the etching gas with respect to the second pixel defining layer.

In an embodiment, each of the patterning of the first insulating layer and the patterning of the second insulating layer may include a dry etching process.

### BRIEF DESCRIPTION OF THE FIGURES

The accompanying drawings are included to provide a further understanding of the invention and are incorporated in and constitute a part of this specification. The drawings illustrate embodiments of the invention and, together with the description, serve to explain embodiments of the invention. In the drawings:

FIG. 1A is a perspective view of an electronic apparatus according to an embodiment of the invention;

FIG. 1B is a block diagram of an electronic apparatus according to the embodiment of the invention;

FIG. 2 is a cross-sectional view illustrating an example of the electronic apparatus shown in FIG. 1A;

FIG. 3 is a cross-sectional view illustrating an example of a display panel shown in FIG. 2;

FIG. 4 is a plan view of the display panel according to an embodiment of the invention;

FIG. 5 is a cross-sectional view of the display panel, taken along line I-I′ of FIG. 4;

FIG. 6 is a plan view of a display panel according to an embodiment of the invention;

FIG. 7 is a plan view of a display panel according to an embodiment of the invention;

FIG. 8A is a cross-sectional view of a display panel according to an embodiment of the invention;

FIG. 8B is a plan view of the display panel according to the embodiment of the invention;

FIG. 9 is a cross-sectional view of a display panel according to an embodiment of the invention;

FIG. 10 is a cross-sectional view of a display panel according to an embodiment of the invention;

FIG. 11 is a cross-sectional view of a display panel according to an embodiment of the invention;

FIGS. 12A and 12P are cross-sectional views illustrating a portion of processes in a method for manufacturing a display panel according to an embodiment of the invention; and

FIGS. 13A and 13B are cross-sectional views illustrating a portion of processes in a method of manufacturing a display panel according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, it will also be understood that when one component (or region, layer, portion) is referred to as being related to another element such as being ‘on’, ‘connected to’, or ‘coupled to’ another component, it can be directly disposed/connected/coupled on/to the one component, or an intervening third component may also be present. In contrast, when one component (or region, layer, portion) is referred to as being related to another element such as being ‘directly on’, ‘directly connected to’, or ‘directly coupled to’ another component, no intervening third component is present.

Like reference numerals refer to like elements throughout. Also, in the figures, the thickness, ratio, and dimensions of components are exaggerated for clarity of illustration.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” The term “and/or” includes any and all combinations of one or more of the associated components.

The terms such as first and second may be used to describe various components, but the components should not be limited by these term. The terms are used solely for the purpose of distinguishing one component from another. For example, a first element referred to as a first element in an embodiment can be referred to as a second element in another embodiment without departing from the scope of the appended claims.

The singular forms include the plural forms as well, unless the context clearly indicates otherwise. Within the Figures and the text of the disclosure, a reference number indicating a singular form of an element may also be used to reference a plurality of the element.

Also, “under”, “below”, “above”, “upper”, and the like are used for explaining relation association of components illustrated in the drawings. The terms may be a relative concept and described based on directions expressed in the drawings.

It will be understood that the term “include” or “comprise”, when used in this specification, specifies the presence of stated features, integers, processes, steps, operations, elements, components, or a combination thereof, but does not preclude the presence or addition of one or more other features, integers, processes, steps, operations, elements, components, or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by a person of ordinary skill in the art to which this invention belongs. In addition, terms such as those defined in commonly used dictionaries should be interpreted as having meanings consistent with their meanings in the context of the relevant technology, and unless explicitly defined, it should not be interpreted in an overly idealistic or overly formal sense.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention are described with reference to the drawings.

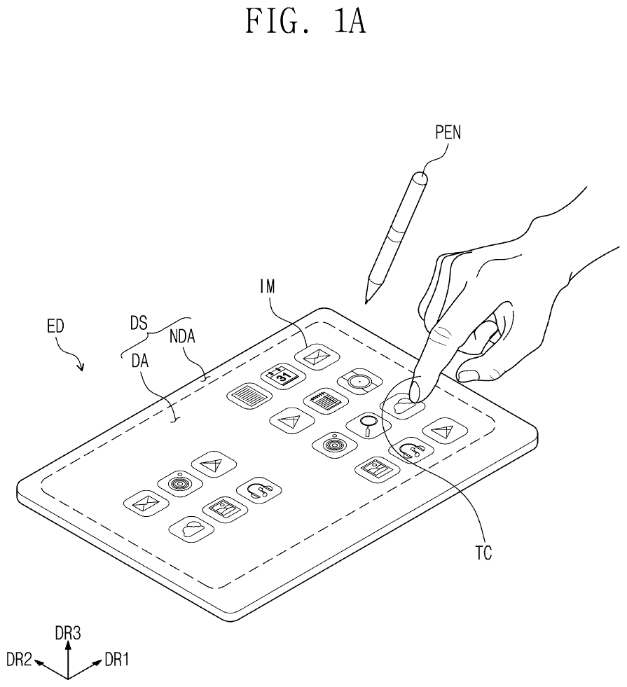

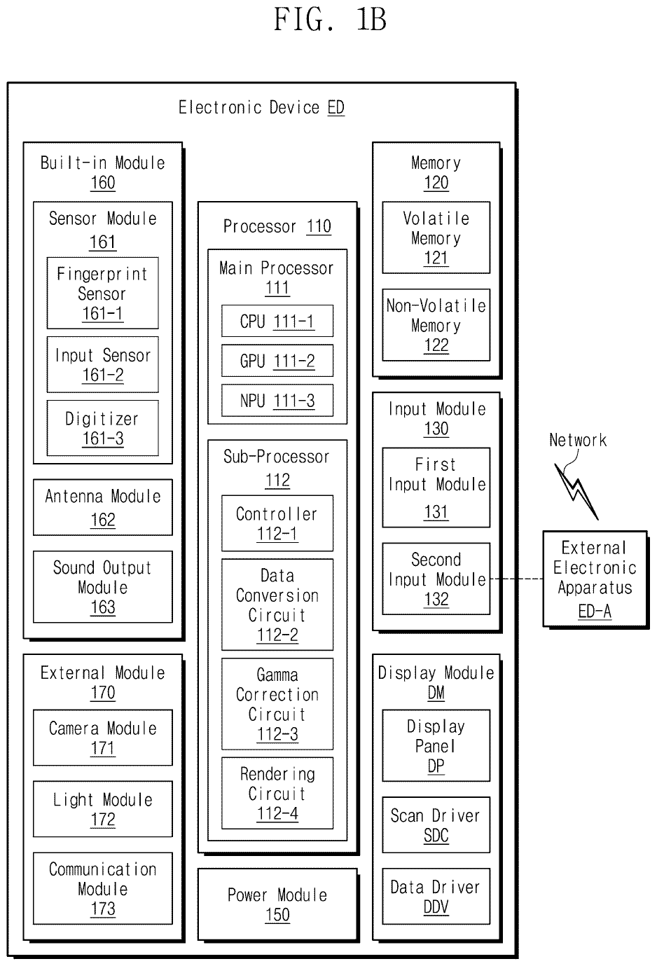

FIG. 1A is a perspective view of an electronic apparatus ED according to an embodiment of the invention. FIG. 1B is a block diagram of the electronic apparatus according to the embodiment of the invention.

Referring to FIG. 1A, an electronic apparatus ED may include long sides extending parallel to a first direction DR1 and short sides extending parallel to a second direction DR2 which intersects the first direction DR1. However, this is merely illustrated as an example. The electronic apparatus ED may include sides having the same length with respect to each of the first direction DR1 and the second direction DR2, but it is not limited thereto.

Hereinafter, a direction which is substantially perpendicular to a plane defined by the first direction DR1 and the second direction DR2 crossing each other may be defined as a third direction DR3. A thickness of the electronic device ED and various components or layers thereof may be defined along the third direction DR3, e.g., a thickness direction. Also, in this description, the expression “when viewed in a plan view” may mean a state when viewed in (or along) the third direction DR3.

A front surface of the electronic apparatus ED may be defined as a display surface DS and may be disposed in a plane parallel to a plane defined by the first direction DR1 and the second direction DR2. Through the display surface DS, images IM generated in the electronic apparatus ED may be provided to outside of the electronic device such as to a user.

The display surface DS may include a display area DA and a non-display area NDA which is adjacent to the display area DA. The display area DA may be an area (e.g., a planar area) at which the image IM is displayed, such as a still image, a moving image like a video, etc. The non-display area NDA may be an area on which the image IM is not displayed. The non-display area NDA may be adjacent to at least one side of the display area DA. In this embodiment, the non-display area NDA may have a frame shape surrounding the display area DA. However, this is illustrated as an example, and in one embodiment of the invention, the non-display area NDA may be omitted, in which case the display surface DS may consist only of the display area DA.

The electronic apparatus ED may detect an external input applied from the outside of the electronic apparatus ED. For example, the electronic apparatus ED may detect a first input caused by a touch TC of an input device and a second input caused by a touch pen PEN as an input device. The touch TC may include various types of external inputs such as contact, hovering, light, heat, or pressure from the input device like a body part of a user's body. The touch pen PEN may be an active pen or an electromagnetic pen, but it is not limited thereto. The touch pen PEN may be defined as an input device, and the display area DA may provide a sensing area capable of detecting an input in addition to displaying images.

In one embodiment, the electronic apparatus ED may be a large electronic apparatus such as a television, monitor, or outdoor billboard. Additionally, the electronic apparatus ED may be a medium or small-sized electronic apparatus such as a personal computer, laptop computer, personal digital assistant, car navigation unit, gaming console, smartphone, tablet, or camera. However, this is merely an example, and other display devices may be employed as long as they do not deviate from the concept of the invention. FIGS. 1A and 1B illustrate an example in which the electronic apparatus ED is a tablet device.

Referring to FIG. 1B, the electronic apparatus ED may output various information through a display module DM within the operating system. When a processor 110 executes an application stored in a memory 120, the display module DM may provide application information to the user via a display panel DP.

The processor 110 may acquire an external input through an input module 130 or a sensor module 161 and execute application corresponding to the external input. For example, when the user selects a camera icon displayed on the display panel DP, the processor 110 may acquire a user input through an input sensor 161-2 and activate a camera module 171. The processor 110 may transmit video data corresponding to a captured image, which is acquired through the camera module 171, to the display module DM. The display module DM may display an image IM corresponding to the captured image through the display panel DP.

As described above, an operation of the electronic apparatus ED has been briefly explained. Hereinafter, the configuration of the electronic apparatus ED will be described in detail. Some of the configurations of the electronic apparatus ED described below may be integrated into a single configuration, or a single configuration may be divided into two or more configurations.

Referring to FIG. 1B, the electronic apparatus ED may communicate with an external electronic apparatus ED-A through a network, such as a short-range wireless communication network or a long-range wireless communication network. According to an embodiment, the electronic apparatus ED may include the processor 110, the memory 120, an input module 130, a display module DM, a power module 150, an internal module 160, and an external module 170. According to an embodiment, at least one of the above-described components of the electronic apparatus ED may be omitted, or one or more other components may be added. According to an embodiment, some of the above-described components, such as a sensor module 161, an antenna module 162, or a sound output module 163, may be integrated into another component, such as the display module DM.

The processor 110 may execute software to control at least one other component of the electronic apparatus ED connected to the processor 110, such as a hardware or software component, and may perform various data processing or calculations. According to an embodiment, as at least part of the data processing or calculations, the processor 110 may store commands or data, which is received from other components, such as the input module 130, the sensor module 161, or a communication module 173, in a volatile memory 121, and process the commands or data stored in the volatile memory 121. The resulting data may be stored in a non-volatile memory 122.

The processor 110 may include a main processor 111 and an auxiliary processor 112. The main processor 111 may include one or more of a central processing unit (CPU) 111-1 or an application processor (AP). The main processor 111 may further include one or more of a graphic processing unit (GPU) 111-2, a communication processor (CP), or an image signal processor (ISP). The main processor 111 may further include a neural processing unit (NPU) 111-3. The neural processing unit is a processor, which specializes for processing artificial intelligence model. The artificial intelligence model may be generated through machine learning. The artificial intelligence model may include a plurality of artificial neural network layers.

The artificial neural network may be one of a deep neural network (DNN), convolutional neural network (CNN), recurrent neural network (RNN), restricted Boltzmann machine (RBM), deep belief network (DBN), bidirectional recurrent deep neural network (BRDNN), deep Q-networks, or any combination of two or more thereof, but is not limited thereto. The artificial intelligence model may include a software structure, in addition to or instead of a hardware structure. At least two of the above-described processing units and processors may be implemented as a single integrated configuration (e.g., a single chip) or as separate configurations (e.g., a plurality of chips).

The auxiliary processor 112 may include a controller 112-1. The controller 112-1 may include an interface conversion circuit and a timing control circuit. The controller 112-1 may receive an image signal from the main processor 111, convert data format of the image signal to match the interface specifications of the display module DM, and output the image data. The controller 112-1 may output various control signals necessary for driving the display module DM.

The auxiliary processor 112 may further include a data conversion circuit 112-2, a gamma correction circuit 112-3, and a rendering circuit 112-4. The data conversion circuit 112-2 may receive image data from the controller 112-1 and compensate the image data to display images at a desired brightness according to the characteristics of the electronic apparatus ED or user settings or may convert the image data to reduce power consumption or compensate for afterimages. The gamma correction circuit 112-3 may convert image data or a gamma reference voltage to provide the image displayed on the electronic apparatus ED with a desired gamma characteristic. The rendering circuit 112-4 may receive the image data from the controller 112-1 and render the image data considering the pixel arrangement of the display panel DP applied to the electronic apparatus ED. At least one of the data conversion circuit 112-2, the gamma correction circuit 112-3, or the rendering circuit 112-4 may be integrated into another component, such as the main processor 111 or the controller 112-1. At least one of the data conversion circuits 112-2, the gamma correction circuit 112-3, or the rendering circuit 112-4 may also be integrated into a data driver DDV described below.

The memory 120 may store various data, such as input data or output data related to commands, which are used by at least one component of the electronic apparatus ED, such as the processor 110 or the sensor module 161. The memory 120 may include at least one of the volatile memory 121 and the non-volatile memory 122.

The input module 130 may receive commands or data to be used by components (e.g., such as the processor 110, the sensor module 161, or the sound output module 163) of the electronic apparatus ED from outside the electronic apparatus ED, such as from the user or an external electronic apparatus ED-A.

The input module 130 may include a first input module 131 which receives commands or data from the user and a second input module 132 which receives commands or data from the external electronic apparatus ED-A. The first input module 131 may include a microphone, a mouse, a keyboard, a key (e.g., a button), or a pen (e.g., a passive pen or an active pen). The second input module 132 may support designated protocols for wired or wireless connections to the external electronic apparatus ED-A. According to an embodiment, the second input module 132 may include an HDMI (high definition multimedia interface), a USB (universal serial bus) interface, an SD card interface, or an audio interface. The second input module 132 may include a connector which physically connects to the external electronic apparatus ED-A, such as an HDMI connector, a USB connector, an SD card connector, or an audio connector (e.g., a headphone connector).

The display module DM provides visual information to the user. The display module DM may include the display panel DP, a scan driver SDC, and the data driver DDV. The display module DM may further include a window, a chassis, and a bracket to protect the display panel DP.

The display panel DP may include a liquid crystal display panel, an organic light-emitting display panel, or an inorganic light-emitting display panel, and the type of display panel DP is not particularly limited. The display panel DP may be of a rigid type, or it may be a flexible type which is rollable or foldable. The display module DM may further include a supporter, a bracket, or a heat dissipation member to support the display panel DP.

The scan driver SDC may be mounted on the display panel DP as a driving chip. Additionally, the scan driver SDC may be integrated into the display panel DP. For example, the scan driver SDC may include an ASG (Amorphous Silicon TFT Gate driver circuit), an LTPS (Low Temperature Polycrystalline Silicon) TFT Gate driver circuit, or an OSG (Oxide Semiconductor TFT Gate driver circuit) embedded in the display panel DP. The scan driver SDC may receive a control signal from the controller 112-1 and, in response to the control signal, output scan signals to the display panel DP.

The display panel DP may further include a light-emitting driver. The light-emitting driver may output a light-emitting control signal to the display panel DP in response to the control signal received from the controller 112-1. The light-emitting driver may be provided separately from the scan driver SDC or may be integrated into the scan driver SDC.

The data driver DDV may receive the control signal from the controller 112-1 and convert the image data into an analog voltage (e.g., a data voltage), in response to the control signal, and output the data voltage to the display panel DP.

The data driver DDV may be integrated into another component (e.g., the controller 112-1). The functions of the interface conversion circuit and the timing control circuit of the above-described controller 112-1 may also be integrated into the data driver DDV.

The display module DM may further include a light-emitting driver and a voltage generation circuit. The voltage generation circuit may output various voltages required for driving the display panel DP.

The power module 150 may supply power to the components of the electronic apparatus ED. The power module 150 may include a battery which charges the supply voltage. The battery may include a non-rechargeable primary cell, a rechargeable secondary cell, or a fuel cell. The power module 150 may include a PMIC (power management integrated circuit). The PMIC may supply optimized power to each of the above-described modules and the modules described below. The power module 150 may include a wireless power transmission/reception member electrically connected to the battery. The wireless power transmission/reception member may include a plurality of antenna radiators in the type of coils.

The electronic apparatus ED may further include the internal module 160 and the external module 170. The internal module 160 may include the sensor module 161, the antenna module 162, and the sound output module 163. The external module 170 may include the camera module 171, a light module 172, and the communication module 173.

The sensor module 161 may detect the input from the user's body or an input from the pen among the first input module 131 and may generate an electrical signal or a data value corresponding to the inputs. The sensor module 161 may include at least one or more of a fingerprint sensor 161-1, an input sensor 161-2, and a digitizer 161-3.

The fingerprint sensor 161-1 may generate the data value corresponding to the user's fingerprint. The fingerprint sensor 161-1 may include either an optical fingerprint sensor or a capacitive fingerprint sensor.

The input sensor 161-2 may generate data value corresponding to coordinate information of inputs from the user's body or a pen. The input sensor 161-2 may generate the data value based on changes in capacitance caused by inputs. The input sensor 161-2 may detect inputs from a passive pen or transmit and receive data with an active pen.

The input sensor 161-2 may also measure a biometric signal, such as blood pressure, moisture, or body fat. For example, when the user contacts a sensor layer or a sensing panel with a part of their body and remains still for a certain period of time, the input sensor 161-2 may detect the biometric signal based on changes in an electric field caused by the part of the body to output desired information to the display module DM.

The digitizer 161-3 may generate the data value corresponding to coordinate information of inputs from the pen. The digitizer 161-3 may generate the data value based on changes in electromagnetism caused by inputs. The digitizer 161-3 may detect the input from the passive pen or transmit and receive data with the active pen.

At least one of the fingerprint sensor 161-1, the input sensor 161-2, or the digitizer 161-3 may be implemented as a sensor layer formed on the display panel DP through a continuous process. The fingerprint sensor 161-1, the input sensor 161-2, and the digitizer 161-3 may be disposed on an upper side of the display panel DP, and any one of the fingerprint sensor 161-1, the input sensor 161-2, and the digitizer 161-3, e.g., the digitizer 161-3, may be disposed on a lower side of the display panel DP.

At least two of the fingerprint sensor 161-1, the input sensor 161-2, or the digitizer 161-3 may be integrated as a single sensing panel through the same process. When the integrated sensing panel is provided, the sensing panel may be disposed between the display panel DP and a window disposed on the upper side of the display panel DP. According to an embodiment, the sensing panel may also be disposed on the window, and the position of the sensing panel is not particularly limited.

At least one of the fingerprint sensor 161-1, the input sensor 161-2, and the digitizer 161-3 may be embedded in the display panel DP. That is, at least one of the fingerprint sensor 161-1, the input sensor 161-2, or the digitizer 161-3 may be simultaneously provided through the process of forming elements (e.g., the light-emitting device or a transistor) included in the display panel DP.

In addition, the sensor module 161 may generate the electrical signal or the data value corresponding to the internal or external state of the electronic apparatus ED. The sensor module 161 may further include, for example, a gesture sensor, a gyro sensor, a barometric sensor, a magnetic sensor, an accelerometer, a grip sensor, a proximity sensor, a color sensor, an infrared (IR) sensor, a biometric sensor, a temperature sensor, a humidity sensor, or an illuminance sensor.

The antenna module 162 may include one or more antennas for transmitting or receiving signals or power to and from an external source. According to an embodiment, the communication module 173 may transmit the signal to the external electronic apparatus or receive the signal from the external electronic apparatus through the antenna suitable for a communication method. The antenna pattern of the antenna module 162 may be integrated into one component (e.g., the display panel DP) of the display module DM, or the input sensor 161-2.

The sound output module 163, which outputs an audio signal to the outside of the electronic apparatus ED, may include a speaker used for general purposes such as multimedia playback or recording playback, and a receiver used exclusively for phone call reception. According to an embodiment, the receiver may be provided integrally with or separately from the speaker. The sound output pattern of the sound output module 163 may be integrated into the display module DM.

The camera module 171 may photograph a still image and video. According to one embodiment, the camera module 171 may include one or more lenses, an image sensor, or an image signal processor. The camera module 171 may further include an infrared camera capable of measuring the presence of a user, the user's position, or the user's gaze.

The light module 172 may provide light. The light module 172 may include a light-emitting diode (LED) or a xenon lamp. The light module 172 may operate in conjunction with the camera module 171 or operate independently.

The communication module 173 may support the establishment of wired or wireless communication channels between the electronic apparatus ED and the external electronic apparatus ED-A and perform communication through the established communication channels. The communication module 173 may include one or more wireless communication modules, such as a cellular communication module, a short-range wireless communication module, or a GNSS (global navigation satellite system) communication module, and one or more wired communication modules, such as a LAN (local area network) communication module or a power line communication module. The communication module 173 may communicate with the external electronic apparatus ED-A through a short-range communication network such as Bluetooth, Wi-Fi Direct, or IrDA (infrared data association), or a long-range communication network such as a cellular network, the Internet, or a computer network (e.g., a LAN or WAN). The various types of communication modules 173 described above may be implemented as a single chip or as separate chips.

The input module 130, the sensor module 161, and the camera module 171 may be used in conjunction with the processor 110 to control the operation of the display module DM.

The processor 110 may output commands or data to the display module DM, the sound output module 163, the camera module 171, or the light module 172 based on input data received from the input module 130. For example, the processor 110 may generate image data corresponding to the input data applied through the mouse or the active pen to output the image data to the display module DM, or may generate command data corresponding to the input data to output the command data to the camera module 171 or the light module 172. The processor 110 may switch the operation mode of the electronic apparatus ED to a low-power mode or a sleep mode when the input data is not received from the input module 130 for a certain period of time, thereby reducing power consumption in the electronic apparatus ED.

The processor 110 may output commands or data to the display module DM, the sound output module 163, the camera module 171, or the light module 172 based on sensing data received from the sensor module 161. For example, the processor 110 may compare authentication data applied by the fingerprint sensor 161-1 with authentication data stored in the memory 120 and execute an application based on the comparison result. The processor 110 may execute commands or output corresponding image data to the display module DM based on sensing data detected by the input sensor 161-2 or the digitizer 161-3. When the sensor module 161 includes the temperature sensor, the processor 110 may receive temperature data measured by the sensor module 161 and may further perform brightness compensation on the image data based on the temperature data.

The processor 110 may receive measurement data regarding the presence of the user, the user's position, or the user's gaze from the camera module 171. The processor 110 may further perform the brightness compensation on the image data based on the measurement data. For example, the processor 110, which determines the presence of the user based on input from the camera module 171, may output brightness-compensated image data to the display module DM through the data conversion circuit 112-2 or the gamma correction circuit 112-3.

Some of the components described above may exchange signals (e.g., commands or data) with each other via communication methods for peripheral devices, such as a bus, GPIO (general-purpose input/output), SPI (serial peripheral interface), MIPI (mobile industry processor interface), or UPI (ultra path interconnect) links. The processor 110 may communicate with the display module DM using a predetermined interface, and, for example, any of the above-described communication methods may be used, but the communication is not limited thereto.

The electronic apparatus ED according to various embodiments disclosed in this document may be provided as various types. The electronic apparatus ED may include, for example, at least one of a portable communication device (e.g., a smartphone), a computing device, a portable multimedia device, a portable medical device, a camera, a wearable device, or a home appliance. The electronic apparatus ED according to embodiments of this document is not limited to the above-described devices.

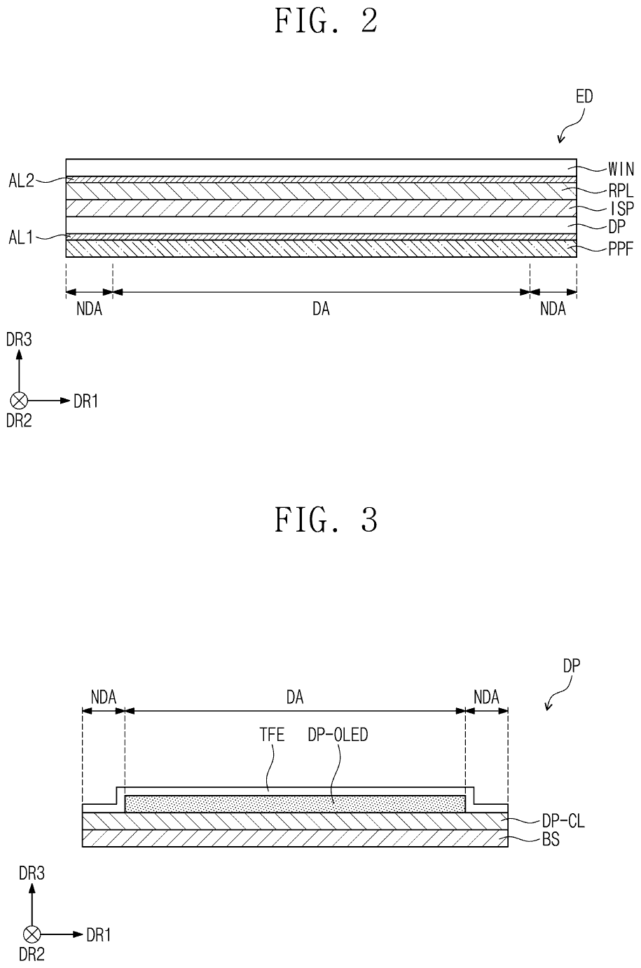

FIG. 2 is a cross-sectional view illustrating an example of the electronic apparatus ED shown in FIG. 1A. FIG. 3 is a cross-sectional view illustrating an example of a display panel DP shown in FIG. 2.

Referring to FIG. 2, the electronic apparatus ED may include the display panel DP, an input sensing unit ISP, a reflection preventing layer RPL, a window WIN, a panel protective film PPF, and first and second adhesive layers AL1 and AL2. The display panel DP may correspond to the above-described display panel DP (see FIG. 1B), and the input sensing unit ISP may correspond to the above-described sensor module 161 (see FIG. 1B).

The display panel DP according to an embodiment of the invention may be an emission type display panel. For example, the display panel DP may include an organic light-emitting display panel or an inorganic light-emitting display panel. An emission layer of the organic light-emitting display panel may include an organic light-emitting material. An emission layer of the inorganic light-emitting display panel may include a quantum dot or a quantum rod. Hereinafter, for example, the display panel DP is described as the organic light-emitting display panel.

Referring to FIG. 3, the display panel DP may include a base layer BS, a circuit element layer DP-CL, a display element layer DP-OLED, and a thin-film encapsulation layer TFE. The circuit element layer DP-CL, the display element layer DP-OLED, and the thin-film encapsulation layer TFE may be sequentially disposed on the base layer BS.

The base layer BS may include glass or a flexible plastic material such as polyimide (PI).

A pixel PX providing in plural including plurality of pixels may be defined by portions of the circuit element layer DP-CL and the display element layer DP-OLED. Each of the pixels PX may include a transistor disposed in the circuit element layer DP-CL and a light-emitting element disposed in the display element layer DP-OLED and connected to the transistor.

The thin-film encapsulation layer TFE as an encapsulation layer may be disposed on the circuit element layer DP-CL to cover the display element layer DP-OLED. The thin-film encapsulation layer TFE may protect the pixels PX from moisture, oxygen, and external foreign substances. In this embodiment, the thin-film encapsulation layer TFE is illustrated as covering the entire area of the base layer BS. However, according to one embodiment of the invention, the base layer BS may include a portion or area, which is exposed from the thin-film encapsulation layer TFE (e.g., exposed to outside the encapsulation layer). Alternatively, an area exposed from the thin-film encapsulation layer TFE may be provided along an edge of the base layer BS such as an outer edge, and the invention is not limited thereto.

Referring to FIG. 2, the input sensing unit ISP may be disposed on the display panel DP. The input sensing unit ISP may include a plurality of sensing parts (not shown) for sensing the external input such as through a capacitive method. The input sensing unit ISP may be directly provided on the display panel DP during the manufacturing (or providing) of the electronic apparatus ED. Specifically, a conductive pattern or insulating layer constituting the input sensing unit ISP may be directly deposited or patterned on an uppermost layer or uppermost surface of the display panel DP. However, the input sensing unit ISP is not limited thereto, and the input sensing unit ISP may be manufactured (or provided) as a separate panel and attached to the display panel DP via an intervening element such as an adhesive layer.

Referring to FIG. 2, the reflection preventing layer RPL may be disposed on the input sensing unit ISP. The reflection preventing layer RPL may reduce the external light reflectance of the electronic apparatus ED, thereby improving the visibility of images displayed on the electronic apparatus ED. The reflection preventing layer RPL may include a phase retarder, a polarizer, a black matrix, or a color filter, and is not limited thereto. The reflection preventing layer RPL may be directly provided on the input sensing unit ISP through coating or deposition processes, or may be provided in the type of a film and attached to the input sensing unit ISP via an intervening layer such as the adhesive layer, but it is not limited thereto.

The window WIN may be disposed on the reflection preventing layer RPL. The window WIN may protect the display panel DP, the input sensing unit ISP, and the reflection preventing layer RPL against scratch and impact from the outside.

The panel protective film PPF may be disposed below the display panel DP. The panel protective film PPF may support the display panel DP and protect a lower portion of the display panel DP. The panel protective film PPF may have insulating properties. For example, the panel protective film PPF may include resins such as polyethylene terephthalate (PET), polyimide (PI), or polypropylene (PP), but the embodiment is not limited thereto.

The first adhesive layer AL1 may be disposed between the display panel DP and the panel protective film PPF, and the display panel DP and the panel protective film PPF may be bonded to each other by the first adhesive layer AL1. The second adhesive layer AL2 may be disposed between the window WIN and the reflection preventing layer RPL, and the window WIN and the reflection preventing layer RPL may be bonded to each other by the second adhesive layer AL2.

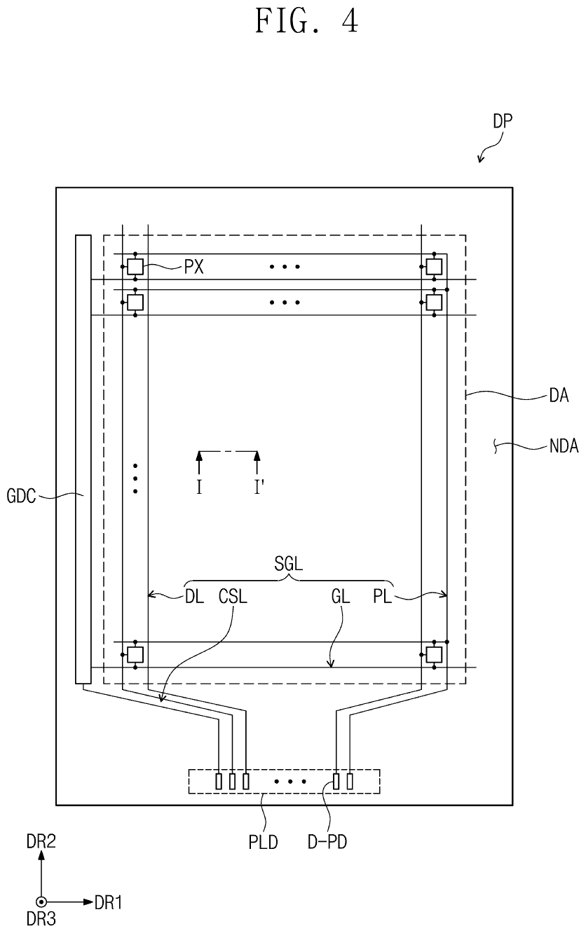

FIG. 4 is a plan view of the display panel DP according to an embodiment of the invention. For ease of explanation, some components of the display panel DP are simplified in FIG. 4.

Referring to FIG. 4, the display panel DP may include pixels PX, signal lines SGL, a driving circuit GDC, and a pad PLD. The display panel DP may include the pixels PX, the signal lines SGL electrically connected to the pixels PX, the driving circuit GDC, and the pad portion PLD.

The pixels PX may be disposed in the display area DA. The pixels PX may be arranged in the first direction DR1 and the second direction DR2. The pixels PX may include a plurality of pixel rows extending in the first direction DR1 and arranged in the second direction DR2, and a plurality of pixel columns extending in the second direction DR2 and arranged in the first direction DR1.

Each of the pixels PX may include the light-emitting device and a pixel circuit for driving the light-emitting device. The light-emitting device may include an organic light-emitting diode (OLED), and the pixel circuit may include at least one transistor connected to the light-emitting device and a capacitor.

The signal lines SGL may include gate lines GL, data lines DL, a power line PL, and a control signal line CSL. Each of the gate lines GL may be connected to a corresponding pixel of the pixels PX, and each of the data lines DL may be connected to a corresponding pixel of the pixels PX. The power line PL may be electrically connected to the pixels PX. The control signal line CSL may be connected to the driving circuit GDC to provide the control signals to the driving circuit GDC.

The driving circuit GDC may include a gate driving circuit. The gate driving circuit may generate gate signals and sequentially output the generated gate signals to the gate lines GL. The gate driving circuit may further output another control signal to the pixel driving circuit.

The pad PLD as a pad area may be a portion or planar area at which a circuit substrate (not shown) external to the display panel DP is connected to the display panel DP. The pad part PLD may include a pixel pad D-PD provided in plural including pixel pads D-PD, and the pixel pads D-PD may be pads at which the flexible circuit board is connected to the display panel DP. Each of the pixel pads D-PD may be connected (e.g., electrically) to a corresponding signal line of the signal lines SGL. One of the pixel pads D-PD may be connected to a control signal line CSL to deliver the control signal to the driving circuit GDC. A portion of the pixel pads D-PD may be connected to the data lines DL to deliver data signals to each of the pixels PX.

Also, the pad PLD may further include input pads (not shown). The input pads may be pads at which a circuit board is connected to the input sensing unit ISP (see FIG. 2). However, the embodiment is not limited thereto, and the input pads may be disposed on the input sensing unit ISP (see FIG. 2) and connected to a circuit board separate from the pixel pads D-PD. Alternatively, the input sensing unit ISP (see FIG. 2) may be omitted, and the input pads may not be included.

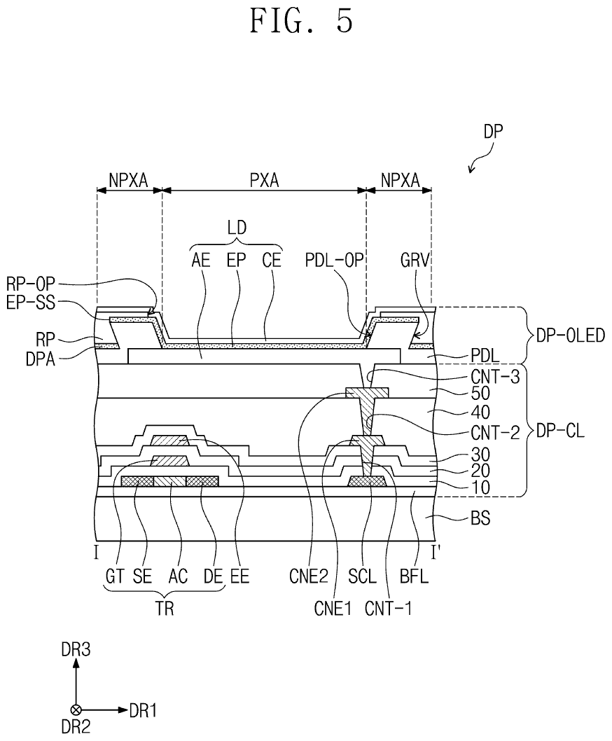

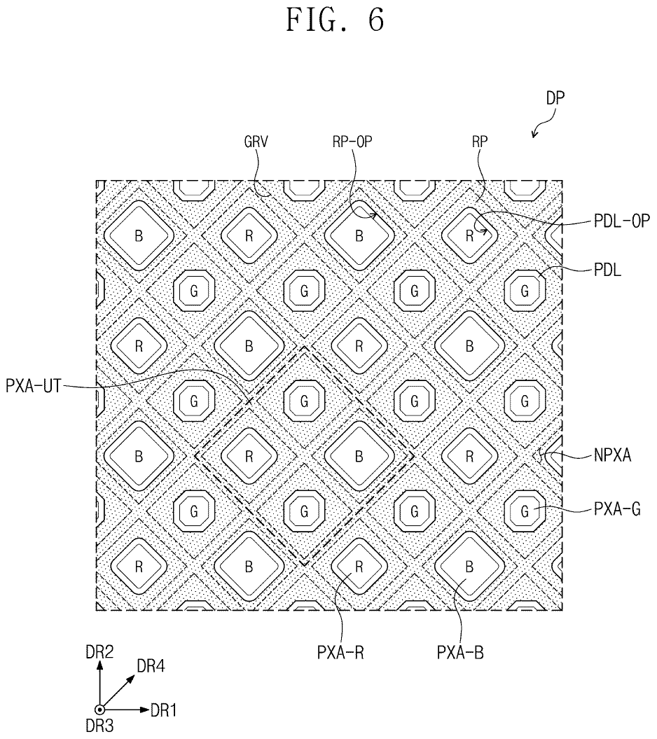

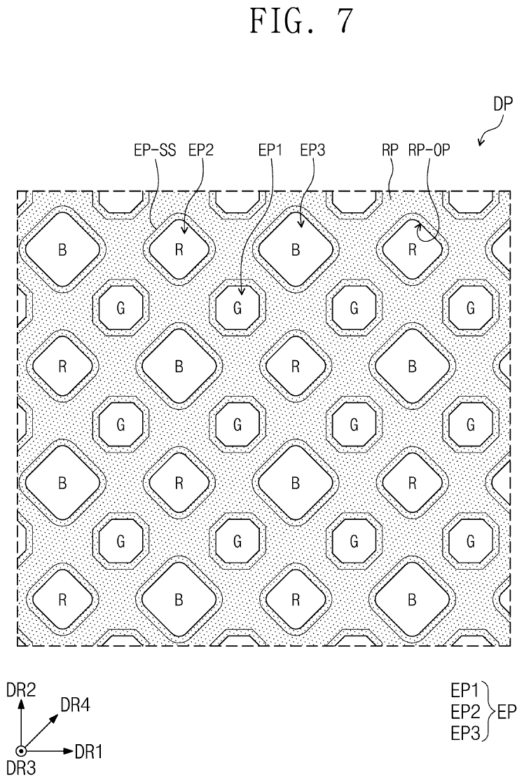

FIG. 5 is a cross-sectional view of a display panel DP according to an embodiment of the invention. FIG. 6 is an enlarged plan view of a display panel DP according to an embodiment of the invention. FIG. 7 is an enlarged plan view of a display panel DP according to an embodiment of the invention.

Referring to FIG. 5, the display panel DP may include a base layer BS, a circuit element layer DP-CL, and a display element layer DP-OLED.

The display panel DP may include a plurality of insulating layers, a semiconductor pattern, a conductive pattern, and a signal line. An insulating layer, a semiconductor layer, and a conductive layer may be provided using methods such as coating or deposition. Subsequently, the insulating layer, semiconductor layer, and conductive layer may be selectively patterned through photolithography and etching. In this way, the semiconductor pattern, the conductive pattern, and the signal line included in the circuit element layer DP-CL and the display element layer DP-OLED may be provided.

Referring to FIG. 5, the circuit element layer DP-CL may be disposed on the base layer BS. The circuit element layer DP-CL may include driving elements, a buffer layer BFL, and first to fifth insulating layers 10, 20, 30, 40, and 50. For ease of explanation, FIG. 5 illustrates a transistor TR, a signal transmission line SCL, and a plurality of connection electrodes CNE1 and CNE2 among the driving elements, as well as the first to fifth insulating layers 10, 20, 30, 40, and 50 sequentially stacked. Meanwhile, this is presented as an example, and the configuration or arrangement of the driving elements constituting the circuit element layer DP-CL may vary and is not limited thereto.

The buffer layer BFL may be disposed on the base layer BS. The buffer layer BFL may enhance the adhesion between the base layer BS and the semiconductor pattern. The buffer layer BFL may include a silicon oxide layer and/or a silicon nitride layer. When the buffer layer BFL includes both a silicon oxide layer and a silicon nitride layer, the two layers may be alternately stacked.

The transistor TR may be disposed on the buffer layer BFL. The transistor TR may include the semiconductor pattern and a gate electrode GT.

The semiconductor pattern may be disposed on the buffer layer BFL. The semiconductor pattern may include polysilicon. However, the embodiment of the invention is not limited thereto. For example, the semiconductor pattern may include amorphous silicon or metal oxide. In FIG. 5, only some semiconductor patterns are illustrated as an example, and at least one or more semiconductor patterns may be further disposed within a plurality of emission areas. The semiconductor pattern may include a plurality of areas distinguished based on conductivity.

The semiconductor pattern may include a source area SE, an active area AC, and a drain area DE. The active area AC may have relatively lower electrical conductivity compared to the source area SE and the drain area DE. The source area SE and the drain area DE may be spaced apart from each other with the active area AC disposed in between.

The gate electrode GT may be disposed between a first insulating layer 10 and a second insulating layer 20. The gate electrode GT may overlap the active area AC of the semiconductor pattern. In this embodiment, the transistor TR is illustrated as having a top-gate structure as an example. However, this is merely an example, and the gate electrode GT may also be disposed below the semiconductor pattern, but it is not limited thereto.

The signal transmission line SCL may have electrical conductivity. In this embodiment, the signal transmission line SCL may be disposed on the same layer as the semiconductor pattern. For example, the signal transmission line SCL may be provided simultaneously with the semiconductor pattern to be in a same layer therewith. In this case, the signal transmission line SCL may be provided as a highly conductive pattern through a doping process applied to the semiconductor pattern. Since the signal transmission line SCL and the semiconductor pattern of the transistor TR are simultaneously provided, the process may be simplified, and process costs may be reduced. However, this is merely an example, and the signal transmission line SCL may be provided by patterning conductive materials such as metal, separately from the semiconductor pattern, or may be disposed on a layer different from the semiconductor pattern, but it is not limited thereto.

As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto.

The source area SE, the active area AC, the drain area DE of the transistor TR, and the signal transmission line SCL may be covered by the first insulating layer 10. The transistor TR may be covered by the second insulating layer 20.

In this embodiment, the circuit element layer DP-CL may further include an upper electrode EE. The upper electrode EE may be disposed between the second insulating layer 20 and the third insulating layer 30. The upper electrode EE may be covered by the third insulating layer 30. The upper electrode EE may at least partially overlap the gate electrode GT. The upper electrode EE may provide a capacitor with the gate electrode GT. The capacitor may be a storage capacitor constituting a portion of a pixel circuit. By further including the upper electrode EE, the capacitor and the transistor TR may be arranged to overlap on a plane (e.g., along the thickness direction), thereby improving the integration density of the pixel circuit and facilitating the design of high-resolution display panel. However, this is merely an example, and the capacitor may be disposed at a position not overlapping the transistor TR, the upper electrode EE and the gate electrode GT may not provide a capacitor, or the upper electrode may be omitted, but it is not limited thereto.

A plurality of connection electrodes CNE1 and CNE2 may be disposed on the buffer layer BFL. The first connection electrode CNE1 may be disposed between the third insulating layer 30 and the fourth insulating layer 40. The first connection electrode CNE1 may pass through the second to third insulating layers 20 and 30 to connect to the signal transmission line SCL.

The second connection electrode CNE2 may be disposed between the fourth insulating layer 40 and the fifth insulating layer 50. The second connection electrode CNE2 may pass through the fourth to fifth insulating layers 40 and 50 to connect to the signal transmission line SCL. The signal flowing through the signal transmission line SCL may be delivered to the display element layer DP-OLED via the first connection electrode CNE1 and the second connection electrode CNE2.

The display element layer DP-OLED may be disposed on the circuit element layer DP-CL. The display element layer DP-OLED may include a pixel defining layer PDL, a light-emitting device LD, and an insulating pattern RP.

The pixel defining layer PDL may be disposed on the fifth insulating layer 50 of the circuit element layer DP-CL. The pixel defining layer PDL may define (or have) a emission opening PDL-OP and a groove GRV, by a solid portion of the pixel defining layer PDL. The solid (material) portion of the pixel defining layer PDL may include an inner surface defining the groove GRV and an outer surface defining the emission opening PDL-OP, among side surfaces or sidewalls of the pixel defining layer PDL. The emission opening PDL-OP may correspond to an anode AE such as at a light emission area, and the pixel defining layer PDL may expose at least a portion of the anode AE to outside the pixel defining layer PDL through the emission opening PDL-OP.

The groove GRV may be spaced apart from the emission opening PDL-OP in a direction along the display element layer DP-OLED. The groove GRV may have a reverse-tapered shape in cross-section. Since the groove GRV is defined in the pixel defining layer PDL, when a material layer for forming the emission layer is deposited on the pixel defining layer PDL, the emission layer may be provided to include separated portions or patterns. This will be described later in detail.

The pixel defining layer PDL may include an inorganic insulating material. For example, the pixel defining layer PDL may include silicon nitride (SiNx).

The light-emitting device LD may include an anode AE (or first electrode), a light-emitting pattern EP, and a cathode CE (or second electrode).

The anode AE may be disposed on the fifth insulating layer 50 of the circuit element layer DP-CL. The anode AE may be a transparent electrode, a semi-transparent electrode, or a reflective electrode. The anode AE may be connected (e.g., electrically) to the second connection electrode CNE2 through a connection contact hole CNT-3 defined penetrating through the fifth insulating layer 50. Accordingly, the anode AE may be electrically connected to the signal transmission line SCL through the first and second connection electrodes CNE1 and CNE2, and electrically connected to a corresponding circuit element. The anode AE may have a single-layer or multi-layer structure. The anode AE may include a plurality of layers including ITO and Ag. For example, the anode AE may include a layer containing ITO (hereinafter, a lower ITO layer), a layer containing Ag disposed on the lower ITO layer (hereinafter, an Ag layer), and a layer containing ITO disposed on the Ag layer (hereinafter, an upper ITO layer). However, the invention is not limited thereto, and the anode AE may be provided as a single layer.

The light-emitting pattern EP may be disposed on the anode AE. The light-emitting pattern EP may include a emission layer containing a light-emitting material. The light-emitting pattern EP may further include a hole injection layer (HIL) and a hole transport layer (HTL) disposed between the anode AE and the emission layer, and an electron transport layer (ETL) and an electron injection layer (EIL) disposed on the emission layer. The light-emitting pattern EP may also be referred to as an “organic layer” or an “intermediate layer.” The light-emitting pattern EP may cover a portion of a top surface of the pixel defining layer PDL.

In one embodiment, the light-emitting pattern EP may be provided in plurality. The plurality of light-emitting patterns EP1, EP2, and EP3 may include a first light-emitting pattern EP1, a second light-emitting pattern EP2, and a third light-emitting pattern EP3. The first light-emitting pattern EP1 may emit first-color light, the second light-emitting pattern EP2 may emit second-color light different from the first-color, and the third light-emitting pattern EP3 may emit third-color light different from the first and second-colors. Side surfaces EP-SS of each of the first to third light-emitting patterns EP1, EP2, and EP3 may be entirely covered by the insulating pattern RP.

The cathode CE may be disposed on the light-emitting pattern EP. The cathode CE may be disposed on the insulating pattern RP described below. The cathode CE may cover the light-emitting pattern EP and the insulating pattern RP.

In this embodiment, the display panel DP may further include a dummy pattern DPA. The dummy pattern DPA may be disposed in the groove GRV, spaced apart from the light-emitting pattern EP. The dummy pattern DPA may include the same material as the light-emitting pattern EP and may be provided through the same process as the light-emitting pattern EP, such as to be in a same layer therewith. Specifically, the dummy pattern DPA may be a provided when a portion of the organic material layer for providing the light-emitting pattern EP is separated at the groove GRV during the organic layer deposition process. That is, a portion of the deposited organic material layer may become the light-emitting pattern EP, and another portion may become the dummy pattern DPA. Meanwhile, the dummy pattern DPA may be removed or may not be provided depending on the embodiment. The dummy pattern DPA may be in contact with the insulating pattern RP. As being in contact, elements may form an interface therebetween. Although FIG. 5 shows the dummy pattern DPA related to the light-emitting pattern EP, it will be understood that a same groove GRV (e.g., at the left and/or the right in FIG. 5) may include two dummy patterns related to two light-emitting patterns EP which are adjacent to each other (e.g., a dummy pattern to the left and/or to the right of the light-emitting pattern EP in FIG. 4). Here, the same groove GRV may include two dummy patterns DPA.

Referring to FIGS. 5 and 6, the insulating pattern RP may be disposed on the pixel defining layer PDL. At least a portion of the insulating pattern RP may be disposed in the groove GRV defined in the pixel defining layer PDL. The insulating pattern RP may be in contact with the inner surface of the pixel defining layer PDL which defines the groove GRV. An insulating pattern opening RP-OP may be defined in the insulating pattern RP. A solid portion (e.g., the insulating pattern RP) and the insulating pattern opening RP-OP may together define an insulating pattern layer. In a planar view, the insulating pattern opening RP-OP may have a surface area greater than that of the emission opening PDL-OP. In an embodiment, the insulating pattern opening RP-OP may overlap the emission opening PDL-OP and have a greater planar area (e.g., along a DR1-DR2 plane) than a planar area of the emission opening PDL-OP.

The display area DA may include a light emission area provided in plural including first to third emission areas PXA-G, PXA-R, and PXA-B, and a non-emission area NPXA surrounding the first to third emission areas PXA-G, PXA-R, and PXA-B. The first to third emission areas PXA-G, PXA-R, and PXA-B may respectively correspond to areas where light provided from the light-emitting device LD is emitted. The first to third emission areas PXA-G, PXA-R, and PXA-B may be distinguished based on the color of the light emitted outward from the display panel DP.

The first to third emission areas PXA-G, PXA-R, and PXA-B may respectively provide first to third-colored light, which are different colors. For example, the first-color light may be green light, the second-color light may be red light, and the third-color light may be blue light. However, the examples of the first to third-color light are not necessarily limited to the above-described examples.

Each of the first to third emission areas PXA-G, PXA-R, and PXA-B may be defined as an area at which a top surface of the anode AE is exposed to outside the pixel defining layer PDL at the emission opening PDL-OP. The non-emission area NPXA may define the boundaries of the first to third emission areas PXA-G, PXA-R, and PXA-B and may prevent color mixing between the first to third emission areas PXA-G, PXA-R, and PXA-B.

Each of the first to third emission areas PXA-G, PXA-R, and PXA-B may be provided in plurality, have a predetermined arrangement pattern in the display area DA, and may be repeatedly arranged. In this embodiment, the first to third emission areas PXA-G, PXA-R, and PXA-B are illustrated as being arranged in a Pentile™ arrangement. Accordingly, two first emission areas PXA-G, one second emission area PXA-R, and one third emission area PXA-B are arranged in a diamond shape to provide a light-emitting unit PXA-UT, which may be repeatedly arranged along the first direction DR1 and the fourth direction DR4. The fourth direction DR4 may be a diagonal direction crossing the first direction DR1 and the second direction DR2. However, this is merely an example, and the first to third emission areas PXA-G, PXA-R, and PXA-B may be arranged in a matrix pattern along the first direction DR1 and the second direction DR2, in a stripe arrangement arranged in a single row, or in a diamond pixel arrangement, but the invention is not limited thereto.

The first to third emission areas PXA-G, PXA-R, and PXA-B may have various shapes in a planar view. For example, the first to third emission areas PXA-G, PXA-R, and PXA-B may have shapes such as polygons, circles, or ellipses. FIG. 6 illustrates the second and third emission areas PXA-R and PXA-B having a quadrangular shape (or diamond shape), and the first emission area PXA-G having an octagonal shape on a plane.

The first to third emission areas PXA-G, PXA-R, and PXA-B may have the same shape in a planar view, or at least some of them may have different shapes. In FIG. 6, the second and third emission areas PXA-R and PXA-B having the same shape in a planar view, and the first emission area PXA-G having a different shape from the second and third emission areas PXA-R and PXA-B are illustratively shown.

At least a portion of the first to third emission areas PXA-G, PXA-R, and PXA-B may have different areas in a planar view. In one embodiment, the area of the second emission area PXA-R, which emits red light, may have a surface area larger than that of the first emission area PXA-G, which emits green light, and smaller than that of the third emission area PXA-B, which emits blue light. However, the relative sizes of the first to third emission areas PXA-G, PXA-R, and PXA-B, based on the emitted color, are not limited thereto and may vary depending on the design of the display panel DP. Furthermore, the first to third emission areas PXA-G, PXA-R, and PXA-B may have the same area in a planar view without being limited thereto.

Meanwhile, the shape, surface area, and arrangement of the first to third emission areas PXA-G, PXA-R, and PXA-B of the display panel DP according to the invention may be variously designed depending on the emitted light color, size, and structure of the display panel DP, but it is not limited to the embodiment shown in FIG. 6.

Referring to FIG. 7, the insulating pattern RP may be in contact with a side surface EP-SS of each of the light-emitting patterns EP1, EP2, and EP3 to cover each of outer edges of the light-emitting patterns EP1, EP2, and EP3. Since the insulating pattern RP entirely covers the side surface EP-SS of the light-emitting patterns EP1, EP2, and EP3, the insulating pattern RP may prevent the light-emitting patterns EP1, EP2, and EP3 from being exposed to the external environment. Since the insulating pattern RP is directly in contact with the inner surface of the pixel defining layer PDL which defines the groove GRV, the insulating pattern RP may prevent moisture or oxygen from penetrating into the light-emitting patterns EP. Accordingly, degradation caused by the exposure of the light-emitting patterns EP1, EP2, and EP3 to the external environment may be prevented or reduced, and an electronic apparatus ED with improved lifespan may be provided.

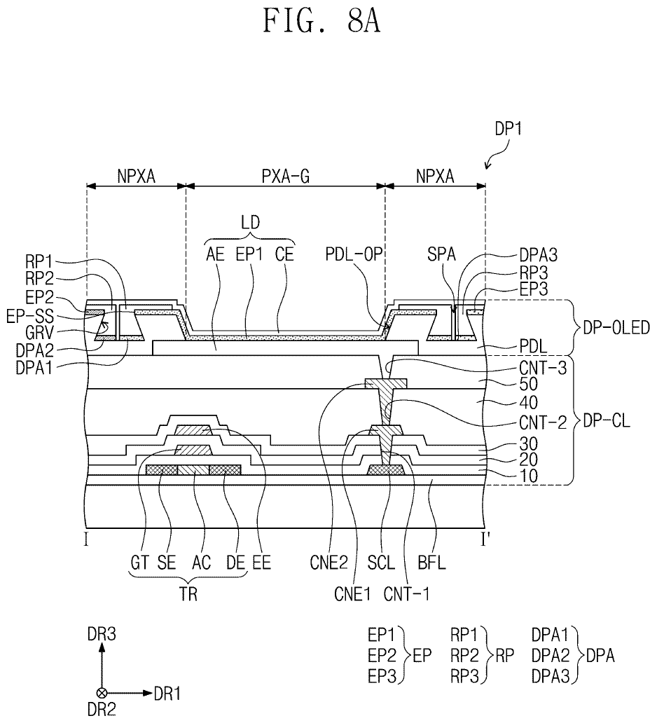

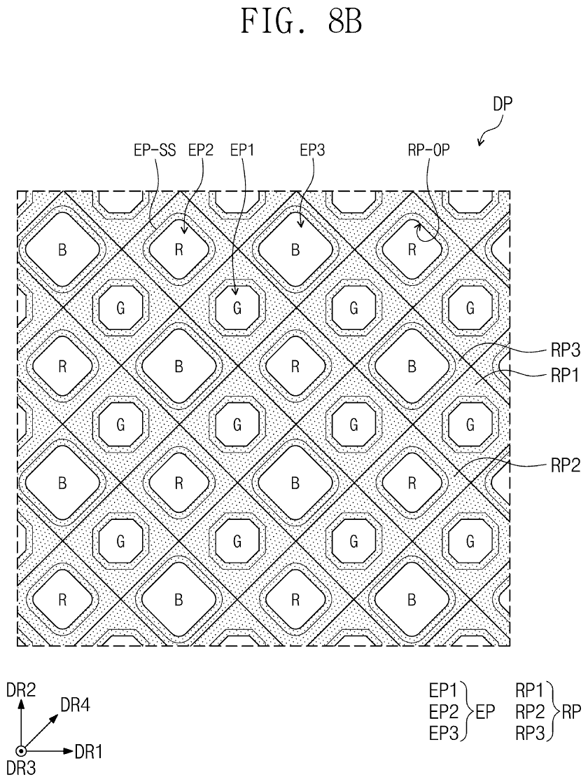

FIG. 8A is a cross-sectional view of a display panel DP1 according to an embodiment of the invention. FIG. 8B is a plan view of the display panel DP1 according to the embodiment of the invention. Referring to FIGS. 8A and 8B for explanation, the same/similar reference numerals are used for the same/similar configurations as those described in FIGS. 5 to 7, and redundant descriptions are omitted.

Referring to FIGS. 8A and 8B, in a display panel DP1, the insulating pattern RP may be divided into a plurality of patterns. Each of the patterns may independently surround the edges of the light-emitting patterns EP. The patterns in which the insulating pattern openings RP-OP are respectively defined, may be spaced apart from each other with a gap therebetween. That is, the insulating pattern layer may have both the insulating pattern openings RP-OP and the gaps defined by solid portions. In this case, the patterns may include a first insulating pattern RP1, a second insulating pattern RP2, and a third insulating pattern RP3 each of which defines an insulating pattern opening RP-OP therein.

Referring to FIG. 8A, for example, a solid material portion of the insulating pattern RP disposed in one groove GRV (e.g., the left groove) may be separated into the first insulating pattern RP1 and the second insulating pattern RP2 with a spacing space SPA (e.g., a gap) therebetween. That is, solid portions of two insulating patterns may be in a same one of the groove GRV. The insulating pattern RP disposed in another groove GRV (e.g., the right groove) may be separated into the first insulating pattern RP1 and the third insulating pattern RP3 with a spacing space SPA therebetween. That is, solid portions of a plurality of insulating patterns RP may be disposed in one groove GRV. The first insulating pattern RP1 may surround the first light-emitting pattern EP1, and the second insulating pattern RP2 may surround the second light-emitting pattern EP2. Additionally, the third insulating pattern RP3 may surround the third light-emitting pattern EP3. Here, solid portions of a light-emitting pattern may be in respective grooves at opposing sides of an emission area.

In this embodiment, dummy patterns DPA1, DPA2, and DPA3 disposed in one groove GRV may be spaced apart from each other. For example, the dummy pattern DPA disposed in one groove GRV may be separated into the first dummy pattern DPA1 and the second dummy pattern DPA2 with a spacing space SPA therebetween. The dummy pattern DPA disposed in another groove GRV may be separated into the first dummy pattern DPA1 and the third dummy pattern DPA3 with a spacing space SPA therebetween. Each of the first to third dummy patterns DPA1, DPA2, and DPA3 may be respectively in contact with the insulating patterns RP. However, the embodiment is not limited thereto, and at least two of the dummy patterns DPA1, DPA2, and DPA3 may be in contact with each other within the groove GRV.

Additionally, in one embodiment, at least two dummy patterns may be in contact with one insulating pattern RP. Referring to FIGS. 5 and 6, for example, the insulating pattern RP extends continuously across the non-emission area NPXA instead of being disconnected at the groove GRV, such that two dummy patterns DPA either in contact with each other or spaced apart from each other with a gap therebetween, within a same groove GRV may both be in contact with the continuous layer insulating pattern RP. In terms of a method of providing the display panel DP, an insulating material layer may be provided after all the light-emitting patterns are formed. Here, the insulating material layer may be patterned to provide the insulating pattern openings RP-OP while maintaining the insulating material layer across the two dummy patterns at the same groove GRV.

The first dummy pattern DPA1 may include the same material as the first light-emitting pattern EP1 and be disposed at opposing sides of the first emission area PXA-G (see FIG. 7). The second dummy pattern DPA2 may include the same material as the second light-emitting pattern EP2 and be disposed at opposing sides of the second emission area PXA-R (see FIG. 7). The third dummy pattern DPA3 may include the same material as the third light-emitting pattern EP3 and be disposed at opposing sides of the third emission area PXA-B (see FIG. 7).

Although FIG. 8A illustrates that the second electrode CE is disposed on the spacing space SPA such as to extend across the gap in the insulating pattern layer, it is not limited thereto, and the second electrode CE may also be disposed within the spacing space SPA. Referring to FIG. 8B, the spacing space SPA is indicated by diagonal lines between the emission areas PXA.

The insulating patterns RP1, RP2, and RP3 may be in contact with the side surfaces EP-SS of the light-emitting patterns EP1, EP2, and EP3. Additionally, the insulating patterns RP1, RP2, and RP3 may be in contact with the inner surface of the pixel defining layer PDL which define the grooves GRV. Side surfaces of each of the insulating patterns RP1, RP2, and RP3 and side surfaces of each of the dummy patterns DPA1, DPA2, and DPA3 may be aligned with each other, that is, coplanar with each other. For example, end surfaces (e.g., side surfaces) of the insulating patterns RP1, RP2, and RP3 and corresponding side surfaces of each of the dummy patterns DPA1, DPA2, and DPA3 which respectively define the spacing space SPA may be coplanar with each other.

The insulating patterns RP1, RP2, and RP3 may fully cover the side surfaces EP-SS of the light-emitting patterns EP1, EP2, and EP3, thereby preventing the light-emitting patterns EP1, EP2, and EP3 from being exposed to the atmosphere. Since the insulating patterns RP1, RP2 and RP3 are directly in contact with the inner surface of the pixel defining layer PDL, the insulating patterns RP1, RP2, and RP3 may reduce or prevent moisture or oxygen from penetrating into the light-emitting patterns EP1, EP2, and EP3. Accordingly, degradation caused by exposure of the light-emitting patterns EP1, EP2, and EP3 to the atmosphere may be prevented or reduced, and an electronic apparatus ED with improved lifespan may be provided.

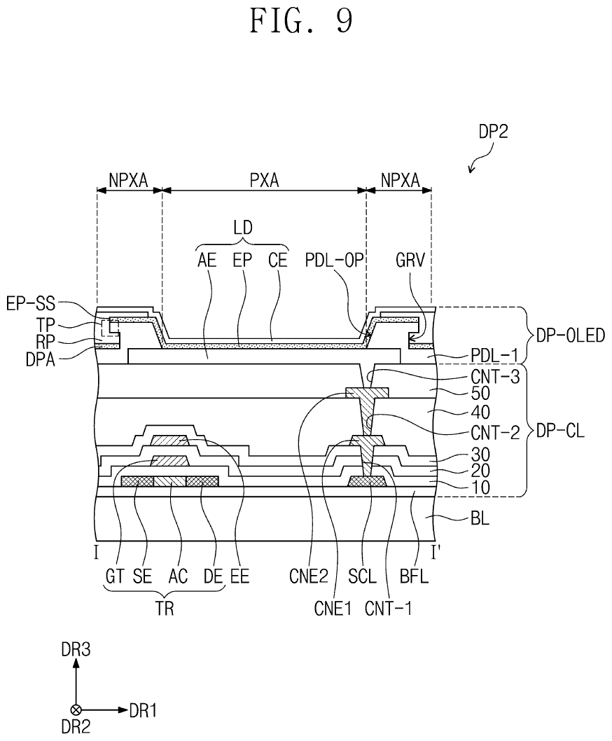

FIG. 9 is a cross-sectional view of a display panel DP2 according to an embodiment of the invention. Hereinafter, with reference to FIG. 9, the same or similar reference numerals as those described in FIGS. 5 to 8 are used for the same or similar components, and redundant descriptions are omitted.

Referring to FIG. 9, the inner surface defining a groove GRV may further define a tip portion TP protruding in a direction parallel to the first direction DR1 in a cross-sectional view. Here, the inner surface is recessed such that sidewall surfaces of the pixel defining layer PDL-1 at a groove GRV are laterally offset from each other to define the tip portion TP. The tip portion TP and the inner surface may be provided by non-curved surfaces of the pixel defining layer PDL-1, without being limited thereto.

The tip portion TP may overlap the dummy pattern DPA in a planar view. An edge of the light-emitting pattern EP may extend along the upper surface of the pixel defining layer PDL-1 to be disposed over the tip portion TP. The tip portion TP may be covered by the insulating pattern RP together with the side surface EP-SS of the light-emitting pattern EP. Since the pixel defining layer PDL-1 further includes the tip portion TP, a light-emitting material for forming the light-emitting pattern EP may be separated at the groove GRV and stably provided in the emission area PXA without requiring additional masks or other processes. This will be described later in detail.

In addition, the insulating pattern RP may be in contact with the inner surface of the pixel defining layer PDL-1 which defines the groove GRV. Since the insulating pattern RP entirely covers the side surface EP-SS of the light-emitting pattern EP, the insulating pattern RP may prevent the light-emitting pattern EP from being exposed to the atmosphere. Since the insulating pattern RP is directly in contact with the inner surface of the pixel defining layer PDL-1, the insulating pattern RP may reduce or prevent moisture or oxygen from penetrating into the light-emitting pattern EP. Accordingly, degradation caused by exposure of the light-emitting pattern EP to the atmosphere may be prevented or reduced, thereby providing an electronic apparatus ED with an improved lifespan.

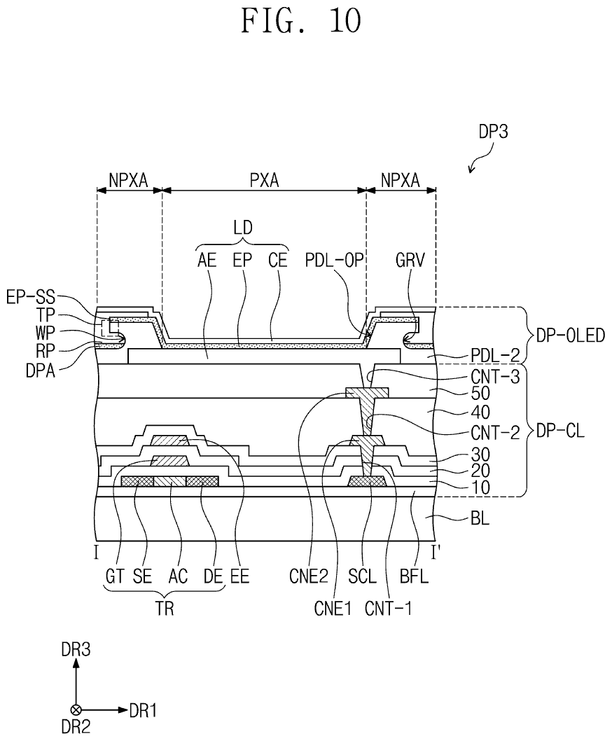

FIG. 10 is a cross-sectional view of a display panel DP3 according to an embodiment of the invention. Hereinafter, with reference to FIG. 10, the same or similar reference numerals are used for the same or similar components described in FIGS. 5 to 9, and redundant descriptions will be omitted.

Referring to FIG. 10, an inner surface of a pixel defining layer PDL-2, which defines the tip portion TP at the groove GRV, may include a curved portion WP in a cross-sectional view. The curved portion WP may be covered by the insulating pattern RP. The groove GRV, defined in the pixel defining layer PDL-2, may have an undercut shape in a cross-sectional view. Accordingly, a material layer for forming the light-emitting pattern EP may be stably provided in the emission area PXA, disconnected at the groove GRV, without requiring an additional mask. This will be described later in detail.

Additionally, the insulating pattern RP may be in contact with the inner surface of the pixel defining layer PDL, which defines the groove GRV, at sidewall surfaces laterally offset from each other and at the lower surface defining the tip portion TP. Since the insulating pattern RP entirely covers the side surface EP-SS of the light-emitting pattern EP, the insulating pattern RP may prevent the light-emitting pattern EP from being exposed to the atmosphere. Since the insulating pattern RP is directly in contact with the inner surface of the pixel defining layer PDL-2 which is at the groove GRV, the insulating pattern RP may reduce or prevent moisture or oxygen from penetrating into the light-emitting pattern EP. Accordingly, degradation caused by exposure of the light-emitting pattern EP to the atmosphere may be prevented or reduced, thereby providing an electronic apparatus ED with an improved lifespan.

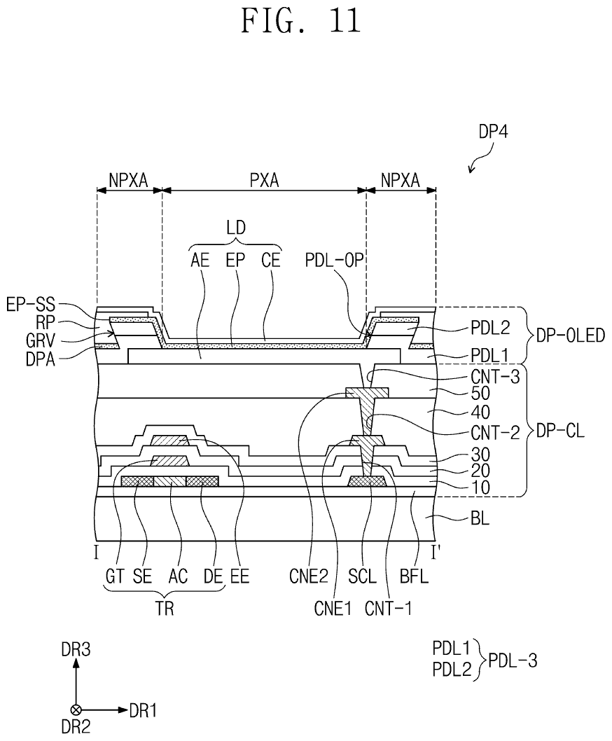

FIG. 11 is a cross-sectional view of a display panel DP4 according to an embodiment of the invention. Hereinafter, with reference to FIG. 11, the same/similar reference numerals are used for the same/similar configurations as those described in FIGS. 5 to 10, and redundant descriptions are omitted.

Referring to FIG. 11, a pixel defining layer PDL-3 may include a plurality of stacked layers respectively defining thickness portions of the pixel defining layer PDL-3. For example, the pixel defining layer PDL-3 may include a first pixel defining layer PDL1 defining a first thickness potion and a second pixel defining layer PDL2 defining a second thickness portion. The second pixel defining layer PDL2 may be disposed on the first pixel defining layer PDL1 and further from the circuit element layer DP-CL than the first pixel defining layer PDL1.

The material of the first pixel defining layer PDL1 may have an etching selectivity relative to the material of the second pixel defining layer PDL2. For example, the first pixel defining layer PDL1 may include silicon nitride, and the second pixel defining layer PDL2 may include silicon oxide. Since the first pixel defining layer PDL1 disposed below the second pixel defining layer PDL2 includes silicon nitride, which has relatively etching ratio higher than that of silicon oxide, a groove GRV having a trench shape may be defined in the pixel defining layer PDL-3 in cross-section.

Additionally, the first pixel defining layer PDL1 may include an organic material, and the second pixel defining layer PDL2 may include an inorganic material. Since the first pixel defining layer PDL1 disposed below the second pixel defining layer PDL2 includes the organic material, which reacts more sensitively to oxygen and moisture compared to inorganic material, a groove GRV having a trench shape may be defined in the pixel defining layer PDL-3 in cross-section.

In an embodiment, the inner surfaces of the first pixel defining layer PDL1 disposed below the second pixel defining layer PDL2 which together define the groove GRV may be coplanar with each other.

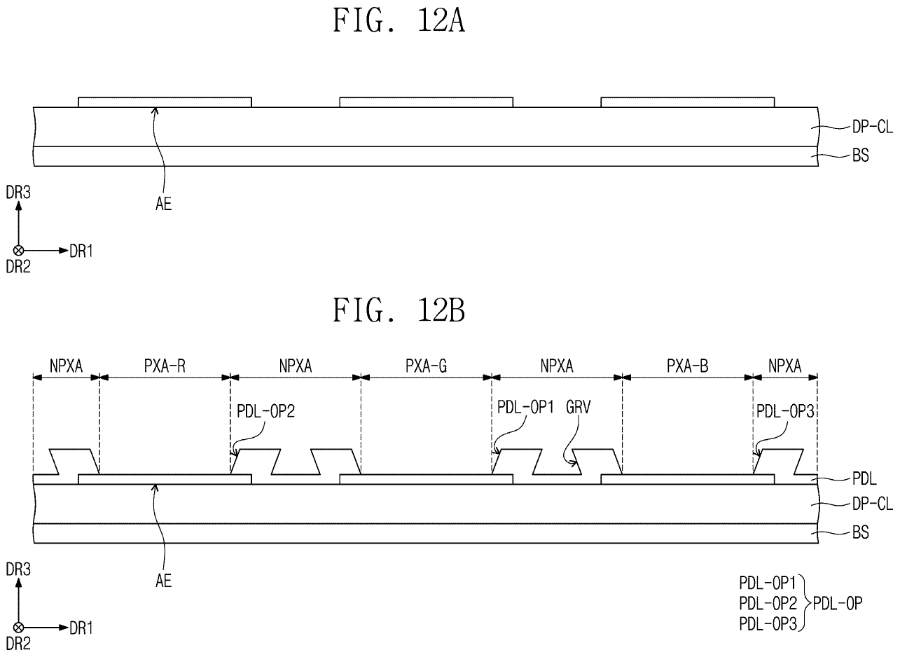

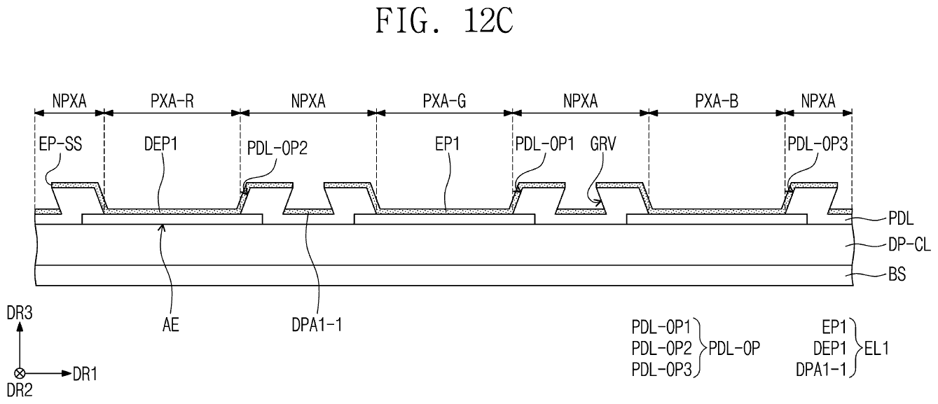

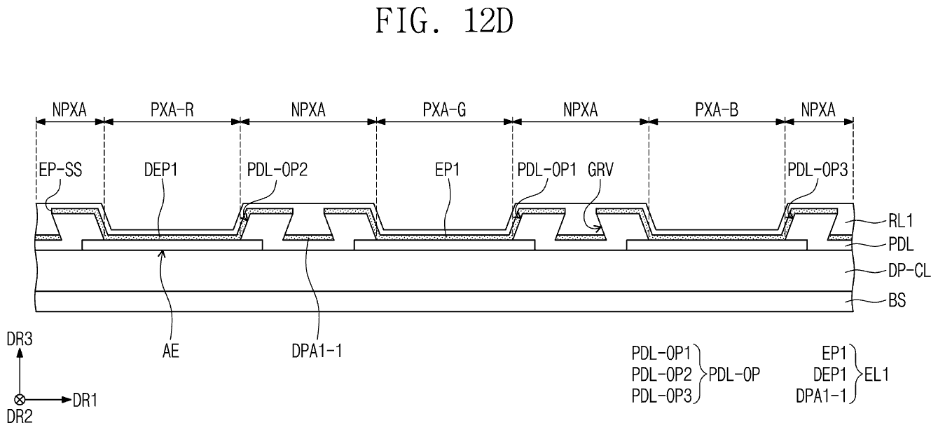

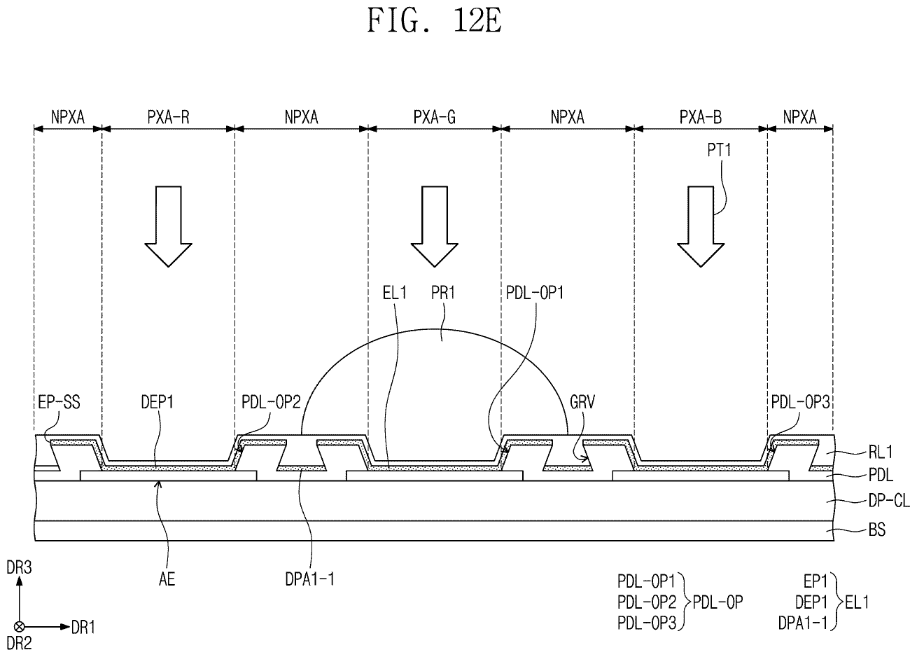

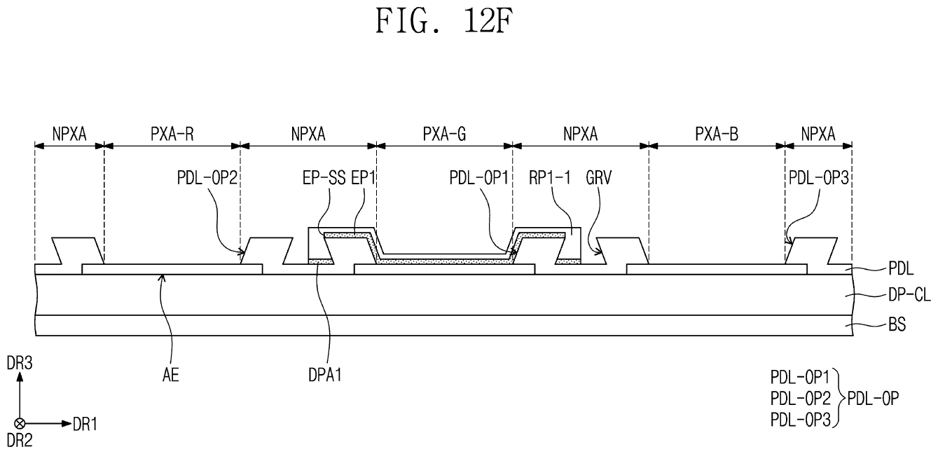

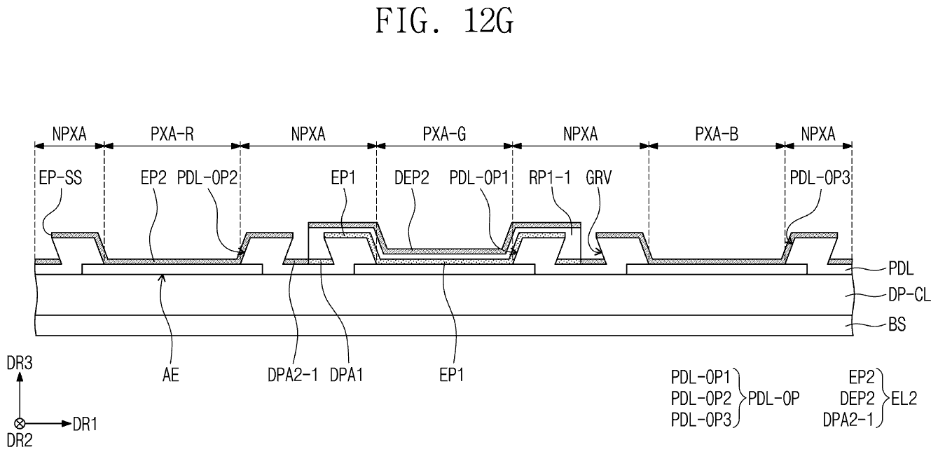

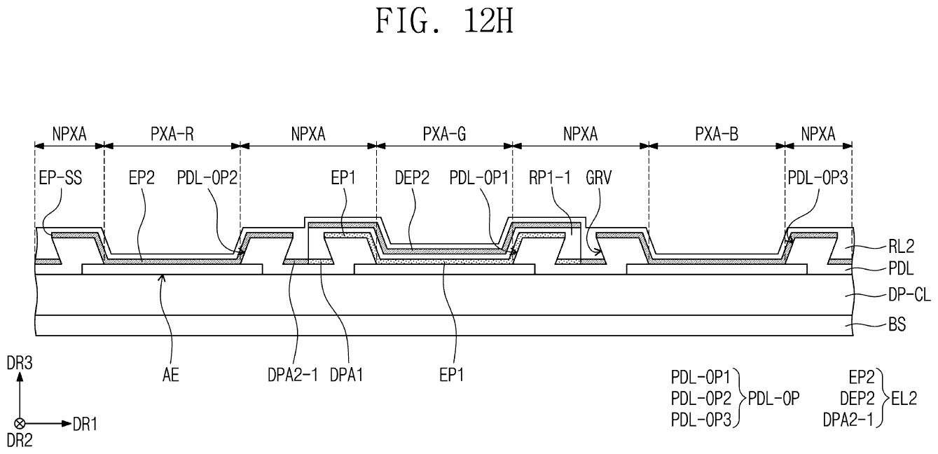

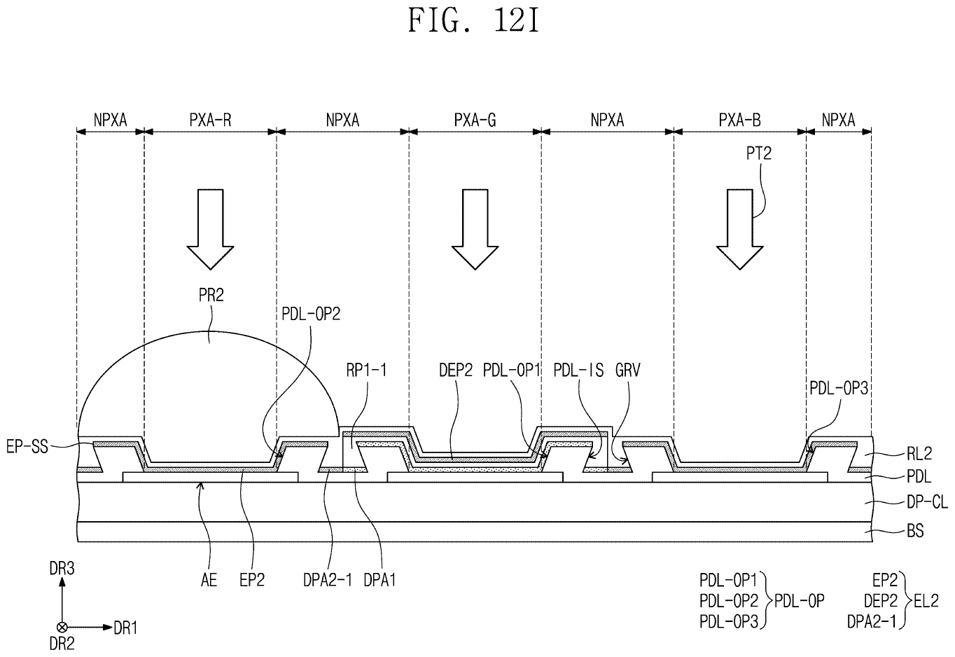

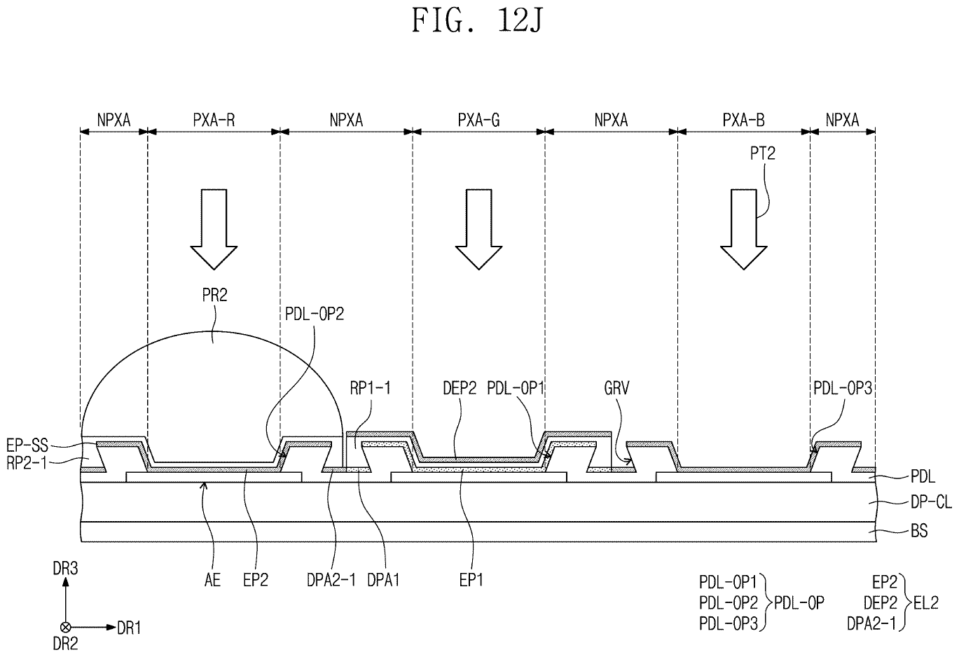

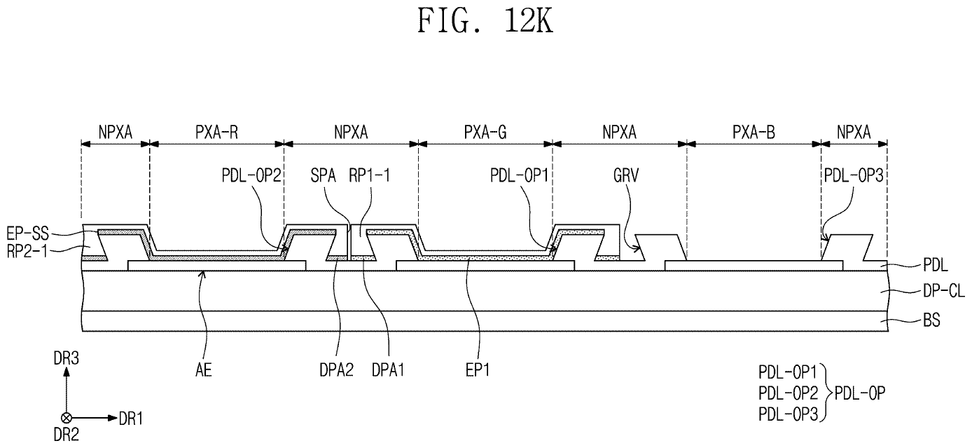

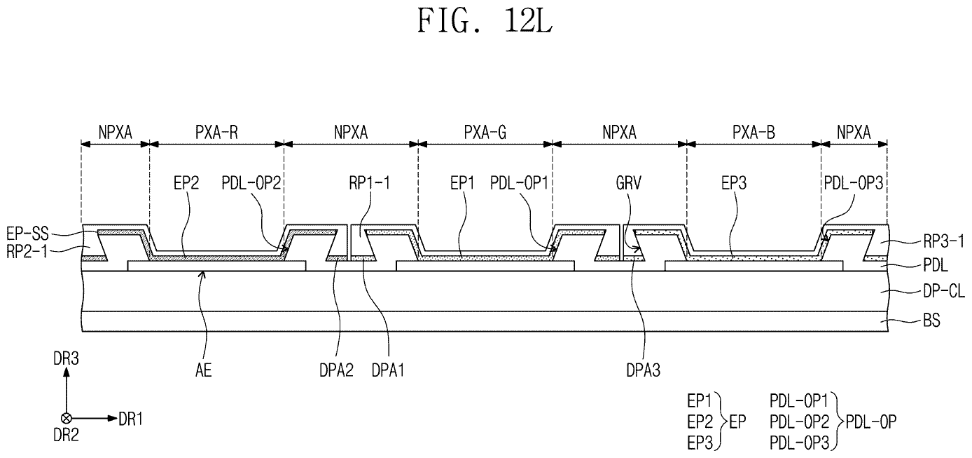

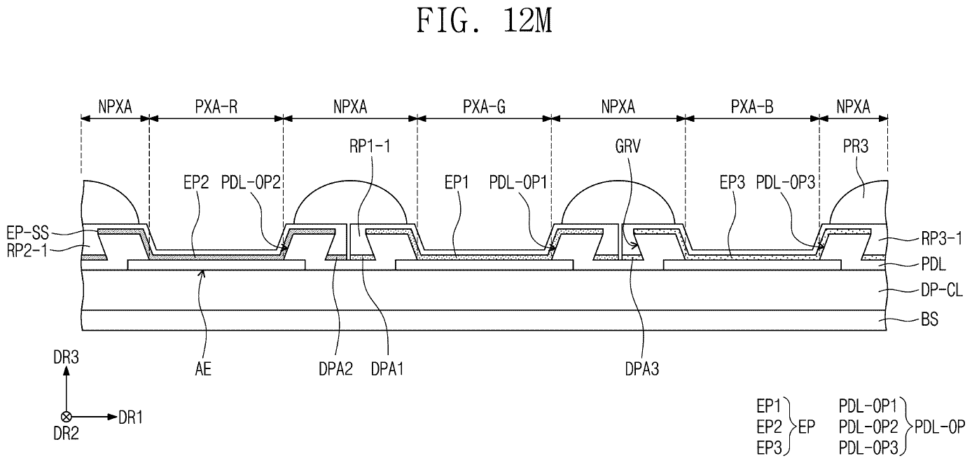

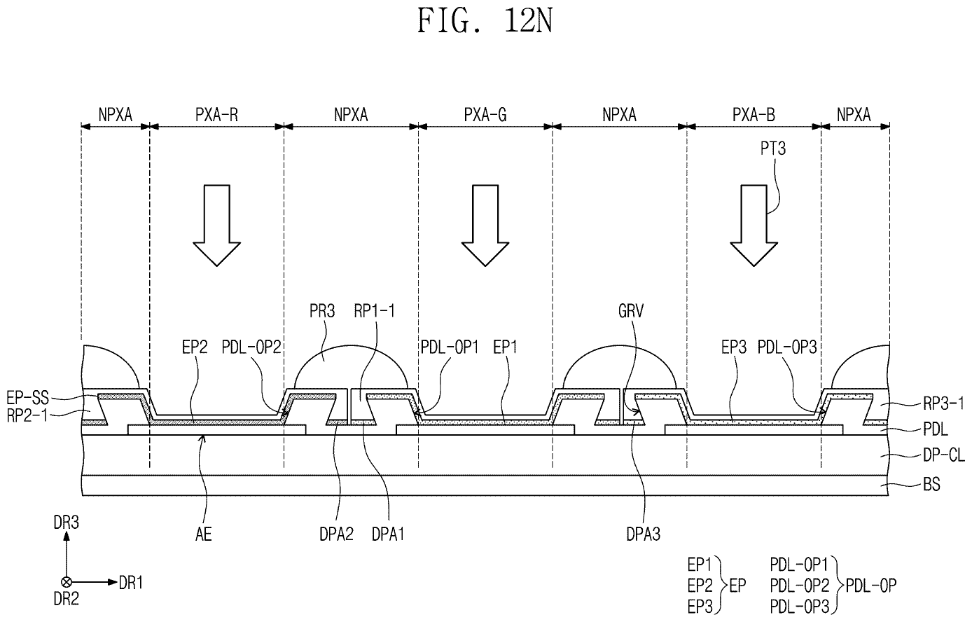

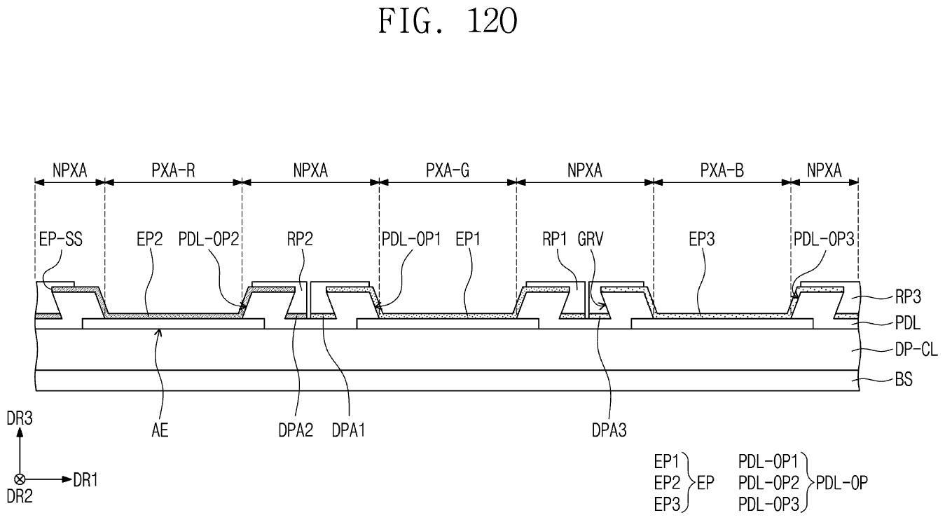

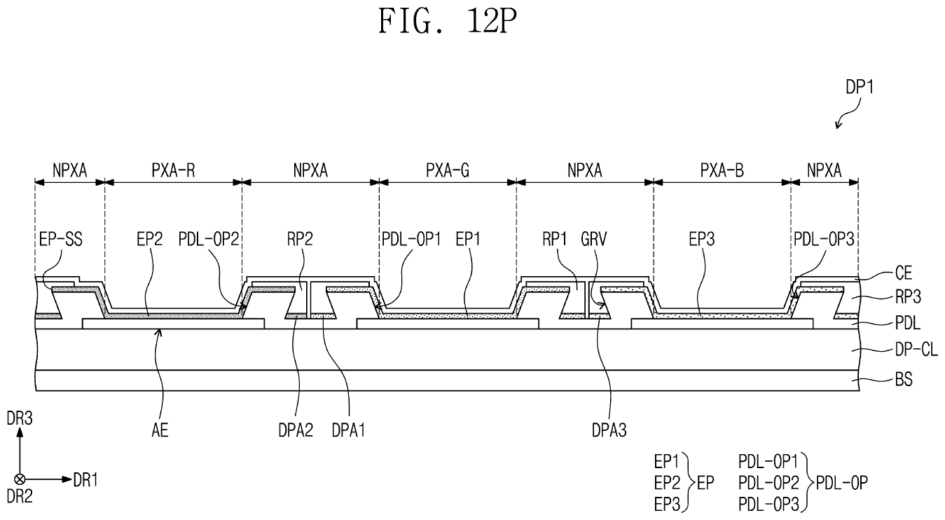

FIGS. 12A to 12P are cross-sectional views illustrating a method for manufacturing (or providing) the display panel DP according to an embodiment of the invention. FIGS. 12A to 12P illustrate a manufacturing method according to an embodiment shown in FIG. 8. Hereinafter, referring to FIGS. 12A and 12P for explanation, the same/similar reference numerals are used for the same/similar configurations as those described in FIGS. 5 to 11, and redundant descriptions are omitted.

Referring to FIG. 12A, first electrodes AE may be formed (or provided) on a base layer BS and a circuit element layer DP-CL. In this embodiment, for the sake of clarity, a circuit element layer DP-CL is illustrated as a single layer, and the components constituting the circuit element layer DP-CL are omitted.

The first electrodes AE may be formed as patterns spaced apart from each other, by coating or depositing a conductive material layer on the circuit element layer DP-CL and then patterning the conductive material layer. Here, the conductive material layer may be formed as a single layer or formed by sequentially stacking a plurality of layers. For example, a first layer made of ITO, a second layer made of Al, and a third layer made of ITO may be sequentially deposited over an entirety of an upper surface of the circuit element layer DP-CL, and then the first to third layers may be patterned using a single mask to form the first electrodes AE. However, this is merely an example, and the number of layers constituting the first electrodes AE is not limited to this embodiment.

Although not illustrated, the circuit element layer DP-CL may be formed through a typical process for manufacturing a circuit element which includes forming insulating layers, semiconductor layers, and conductive layers by coating, deposition, or the like, and selectively patterning the insulating layers, semiconductor layers, and conductive layers through photolithography and etching processes to form semiconductor patterns, conductive patterns, and signal lines.

Referring to FIG. 12B, after the first electrodes AE are formed, a pixel defining layer PDL may be formed. The pixel defining layer PDL may be formed by forming an insulating material layer covering the first electrodes AE and then patterning the insulating material layer. During the patterning process, a plurality of emission openings PDL-OP and grooves GRV may be defined by solid potions of the insulating material layer. The emission openings PDL-OP and the grooves GRV may be formed simultaneously using a single mask, which includes a full-tone area defined for openings corresponding to the emission areas PXA-G, PXA-R, and PXA-B, and a half-tone region defined for the grooves GRV corresponding to the non-emission areas NPXA. Alternatively, the emission openings PDL-OP and the grooves GRV may be sequentially defined using different masks, and the invention is not limited thereto.

Meanwhile, in FIG. 12B, the pixel defining layer PDL is illustratively shown as a single layer (e.g., a monolayer along the thickness direction). However, this is not limited thereto, and the pixel defining layer PDL may also be formed in plural including material layers. For example, after forming the first pixel defining layer PDL1 (see FIG. 11), a second pixel defining layer PDL2 (see FIG. 11) may be formed on the first pixel defining layer PDL1. In this case, the emission openings PDL-OP and the grooves GRV may be formed by etching the first pixel defining layer PDL1 and the second pixel defining layer PDL2 using an etching gas. An etching rate of the etching gas for the first pixel defining layer PDL1 may be higher than that for the second pixel defining layer PDL2. For example, the first pixel defining layer PDL1 may include silicon nitride, and the second pixel defining layer PDL2 may include silicon oxide. Alternatively, the first pixel defining layer PDL1 may include an organic material, and the second pixel defining layer PDL2 may include an inorganic material. Since the first pixel defining layer PDL1, disposed below the second pixel defining layer PDL2, has a relatively faster etching rate than that of the second pixel defining layer PDL2, a groove GRV having a trench shape may be defined in the pixel defining layer PDL in cross-section. The emission openings PDL-OP and the grooves GRV according to an embodiment of the invention may be formed using various methods and are not limited thereto.

Referring to FIG. 12C, a first emission layer EL1 may be formed on the pixel defining layer PDL. A first emission material for providing the first emission layer EL1 may be deposited and formed over the entire surface of the pixel defining layer PDL. The first emission layer EL1 may be a green emission layer. The first emission layer EL1 may include the first emission patterns EP1 of first emission openings PDL-OP1, which overlap first emission openings PDL-OP1, and first dummy emission patterns DEP1 which overlap second and third emission openings PDL-OP2 and PDL-OP3.

That is, the first emission layer EL1 may include the first emission patterns EP1 disposed in the first emission openings PDL-OP1 and the first dummy emission patterns DEP1 disposed in remaining emission openings including the second and third emission openings PDL-OP2 and PDL-OP3.

In the process of forming the first emission layer EL1, a first preliminary dummy pattern DPA1-1 may be formed, separated and disconnected from the first emission patterns EP1 and the first dummy emission patterns DEP1. The first preliminary dummy pattern DPA1-1 may be partially separated during the process of forming the first emission layer EL1 due to the groove GRV defined in the pixel defining layer PDL, and may be formed simultaneously with the first emission patterns EP1 and the first dummy emission patterns DEP1. Here, the first preliminary dummy pattern DPA1-1 may be formed in the groove GRV. Here, the first emission patterns EP1, the first dummy emission patterns DEP1 and the first preliminary dummy pattern DPA1-1 include a same first color emission material. The side surfaces EP-SS of the first emission pattern EP1 is an end surface closest to the groove GRV or furthest from the first electrode AE in a direction along the circuit element layer DP-CL.

Referring to FIG. 12D, a first insulating layer RL1 may be formed on the first emission layer EL1 of the same first color emission material. The first insulating layer RL1 may be deposited on entire surface of the first emission layer EL1. Here, the first insulating layer RL1 may be deposited using atomic layer deposition ALD (atomic layer deposition). The first insulating layer RL1 may include silicon nitride, silicon oxide, and aluminum oxide. The first insulating layer RL1 may be formed to cover a top and side surfaces EP-SS of each of the first emission patterns EP1. The first insulating layer RL1 may be formed to contact the inner surface of the pixel defining layer PDL, which defines the groove GRV. The first insulating layer RL1 may be formed as an integrated layer which is in contact with each of the first emission patterns EP1, the first dummy emission patterns DEP1 and the first preliminary dummy pattern DPA1-1. However, this embodiment is not limited thereto.

Subsequently, referring to FIGS. 12E and 12F, a first photoresist layer PR1 may be formed on the first insulating layer RL1. The first photoresist layer PR1 may be formed to overlap the first emission openings PDL-OP1. The first photoresist layer PR1 may also be partially overlapped with the groove GRV and non-overlapping a remainder of the pixel defining layer PDL. The first insulating layer RL1 may be patterned by providing an etching gas PT1 (or an etching solution) onto the first photoresist layer PR1 while using the first photoresist layer PR1 as a mask. The first insulating layer RL1 may be patterned to form a first preliminary insulating pattern RP1-1. The first preliminary insulating pattern RP1-1 may be patterned into a planar shape which overlaps the first emission area PXA-G. The first insulating layer RL1 may be patterned through a dry etching process. However, this embodiment is not limited thereto.

Additionally, an etching gas may be provided onto the first photoresist layer PR1 to remove at least a portion of the first dummy emission patterns DEP1 of the first emission layer EL1. At least a portion of the first dummy light-emitting patterns DEP1 of the first emission layer EL1 may be removed, thereby forming the first light-emitting patterns EP1. The first light-emitting patterns EP1 may overlap the first emission area PXA-G.

Here, the process of forming the first preliminary insulating pattern RP1-1 and the process of forming the first emission patterns EP1 may be performed simultaneously. Thus, the first preliminary insulating pattern RP1-1 and the first light-emitting patterns EP1 may be patterned within a single process using a single mask.

In the process of forming the first preliminary insulating pattern RP1-1 and the first light-emitting patterns EP1, the first preliminary dummy pattern DPA1-1 may also be patterned simultaneously to form the first dummy pattern DPA1 by removal of portions of the first preliminary dummy pattern DPA1-1 except for portions thereof overlapping the first photoresist layer PR1.

Referring to FIG. 12F, an entirety of the first emission layer EL1 and an entirety of the first insulating layer RL1, except for portions thereof overlapping the first photoresist layer PR1, may be removed to provide the first preliminary insulating pattern RP1-1, the first emission patterns EP1 and the first dummy pattern DPA1 of a first emission area structure.

Referring to FIG. 12G, a second emission material for providing a second emission layer EL2 may be formed on the first light-emitting patterns EP1 and the first preliminary insulating pattern RP1-1 of the first emission area structure. The second emission layer EL2 may be a red emission layer. The second emission layer EL2 may be formed to include second light-emitting patterns EP2 overlapping the second emission openings PDL-OP2 and second dummy light-emitting patterns DEP2 overlapping the first and third emission openings PDL-OP1 and PDL-OP3. That is, the second emission layer EL2 may include the second light-emitting patterns EP2 disposed within the second emission openings PDL-OP2 and the second dummy light-emitting patterns DEP2 disposed at remaining emission openings, that is, within the first and third emission openings PDL-OP1 and PDL-OP3.

In the process of forming the second emission layer EL2, a second preliminary dummy pattern DPA2-1, separated from the second light-emitting patterns EP2 and the second dummy light-emitting patterns DEP2, may also be formed simultaneously. The second preliminary dummy pattern DPA2-1 may be partially separated during the process of forming the second emission layer EL2 due to the groove GRV defined in the pixel defining layer PDL, and may be formed simultaneously with second emission patterns EP2 and a second dummy emission patterns DEP2. Here, the second preliminary dummy pattern DPA2-1 may be formed in the groove GRV.

Referring to FIG. 12H, a second insulating layer RL2 may be formed on the second emission layer EL2. The second insulating layer RL2 may be deposited on the entire surface of the second emission layer EL2. Here, the second insulating layer RL2 may be deposited by atomic layer deposition (ALD). The second insulating layer RL2 may include an oxide, a nitride, or an oxynitride. For example, the second insulating layer RL2 may include silicon nitride, silicon oxide, and aluminum oxide. The second insulating layer RL2 may be formed to cover a top and side surfaces EP-SS of the second light-emitting patterns EP2. The second insulating layer RL2 may also be formed to contact the inner side surface of the pixel defining layer PDL which defines the groove GRV. The second insulating layer RL2 may include a stepped portion in the area adjacent to an end of the first light-emitting pattern EP1 and the first preliminary insulating pattern RP1-1.

Referring to FIGS. 12I and 12J, a second photoresist layer PR2 may be formed on the second insulating layer RL2. The second photoresist layer PR2 may be formed to overlap the second emission openings PDL-OP2. The second photoresist layer PR2 may also be formed to partially overlap the groove GRV at opposing sides of the second emission opening PDL-OP2. By using the second photoresist layer PR2 as a mask, an etching gas PT2 may be provided onto the second photoresist layer PR2 to pattern the second insulating layer RL2. The second insulating layer RL2 may be patterned to form a second preliminary insulating pattern RP2-1 which is spaced apart from the first preliminary insulating pattern RP1-1 by a gap (e.g., the spacing space SPA).

The second preliminary insulating pattern RP2-1 may be patterned in a planar shape which overlaps the second emission area PXA-R. When the second insulating layer RL2 is patterned, the second emission layer EL2 may serve as a mask for the first preliminary insulating pattern RP1-1 such that the first preliminary insulating pattern RP1-1 is not further etched and is maintained within the first emission area structure. The second insulating layer RL2 may be patterned through a dry etching process. However, this embodiment is not limited thereto.

Referring to FIG. 12J, an etching gas PT2 may remove at least a portion of the second dummy light-emitting patterns DEP2 of the second emission layer EL2 except for portions thereof overlapping the second photoresist layer PR2.

FIG. 12K illustrates a state after the second photoresist layer PR2 has been removed. At least a portion of the second dummy light-emitting patterns DEP2 of the second emission layer EL2 may be removed to form the second light-emitting patterns EP2. The second light-emitting patterns EP2 may overlap the second emission area PXA-R. Here, the second light-emitting patterns EP2 may be formed after the second preliminary insulating pattern RP2-1 has been formed.

In the process of forming the second preliminary insulating pattern RP2-1 and the second light-emitting patterns EP2, the second preliminary dummy pattern DPA2-1 may also be patterned simultaneously, forming the second dummy pattern DPA2. Referring to FIG. 12K, an entirety of the second emission layer EL2 and an entirety of the second insulating layer RL2, except for portions thereof overlapping the second photoresist layer PR2, may be removed to provide the second preliminary insulating pattern RP2-1, the second emission patterns EP2 and the second first dummy pattern DPA2 of a second emission area structure.

Meanwhile, a predetermined spacing space SPA may be defined between the second preliminary insulating pattern RP2-1 and the first preliminary insulating pattern RP1-1. That is, a gap is defined between the first and second emission area structures. Accordingly, portions of the second preliminary dummy pattern DPA2-1 and the first dummy pattern DPA1, which are disposed below the second insulating layer RL2 and the first preliminary insulating pattern RP1-1, exposed through the spacing space SPA, may be removed together by the etching gas PT2. As a result, the dummy patterns DPA1 and DPA2 provided in the same groove GRV and adjacent to each other may be formed in a spaced-apart shape. However, this is merely an example, and depending on the process method, the spacing space SPA may not be defined, and the dummy patterns DPA1 and DPA2 may be formed in a state in which they are in contact with each other, but it is not limited thereto.

At a same groove GRV, ends of adjacent light-emitting patterns may be exposed. The insulating patter which extends across or into the groove GRV may cover the ends of the adjacent light-emitting patterns and inner surfaces of the pixel defining layer PDL which define the groove GRV.

Subsequently, referring to FIG. 12L, the method for manufacturing the display panel DP of the invention may further include a process of forming the third preliminary insulating pattern RP3-1 and the third light-emitting pattern EP3 through the same process described in FIGS. 12C through 12K. By using a photoresist mask, a third insulating layer may be etched, and at least a portion of the third emission layer may be removed to form a third preliminary insulating pattern RP3-1 and a third light-emitting pattern EP3 of a third emission area structure. The third preliminary insulating pattern RP3-1 may be patterned to overlap the third emission area PXA-B. The third light-emitting pattern EP3 may overlap the third emission area PXA-B.

Top surfaces of the first preliminary insulating pattern RP1-1, the second preliminary insulating pattern RP2-1, and the third preliminary insulating pattern RP3-1 may be formed on the same layer. That is, the top surfaces may be coplanar with each other. Additionally, top surfaces of the first light-emitting pattern EP1, the second light-emitting pattern EP2, and the third light-emitting pattern EP3 may also be formed on the same layer, that is, coplanar with each other. However, the embodiment is not limited thereto.

FIG. 12L includes a preliminary insulating pattern overlapping each of the first, second and third emission area structures. Here, the preliminary insulating pattern extends across the first electrode AE and across an entirety of a corresponding light-emitting pattern.

Referring to FIG. 12M, the third photoresist layer PR3 may be formed on the first, second and third preliminary insulating patterns RP1-1, RP2-1 and RP3-1. The third photoresist layer PR3 may overlap the grooves GRV while being spaced apart from the emission openings PDL-OP.

Referring to FIGS. 12N and 12O, by providing an etching gas PT3 onto the third photoresist layer PR3, the first, second and third preliminary insulating patterns RP1-1, RP2-1 and RP3-1 may be patterned. The first, second and third preliminary insulating patterns RP1-1, RP2-1 and RP3-1 may be patterned to form the insulating pattern RP and the insulating pattern opening RP-OP. The etching gas PT3 may react with the insulating materials forming the first to third preliminary insulating patterns RP1, RP2, and RP3, while it may not react with the light-emitting patterns EP1, EP2, and EP3.

The providing of the insulating pattern RP and the insulating pattern opening RP-OP, the light-emitting patterns EP1, EP2, and EP3 are exposed to outside the insulating pattern RP at the emission areas PXA. At the non-emission areas NPXA, the side surfaces EP-SS are covered at the groove GRV and protected during subsequent operations.

Referring to FIG. 12P, a second electrode CE may be formed on the light-emitting patterns EP and the insulating pattern RP. The second electrode CE may be formed by coating or depositing a conductive layer on the light-emitting patterns EP1, EP2, and EP3 and the insulating pattern RP, and then patterning the conductive layer. According to the invention, since the insulating pattern RP covers the side surfaces EP-SS of the light-emitting patterns EP1, EP2, and EP3, the side surfaces EP-SS of the light-emitting patterns EP1, EP2, and EP3 may remain unexposed to the external atmosphere even during the formation of the second electrode CE and/or after an encapsulation layer (not shown) is formed. As a result, an electronic apparatus ED with improved reliability and lifespan may be provided.

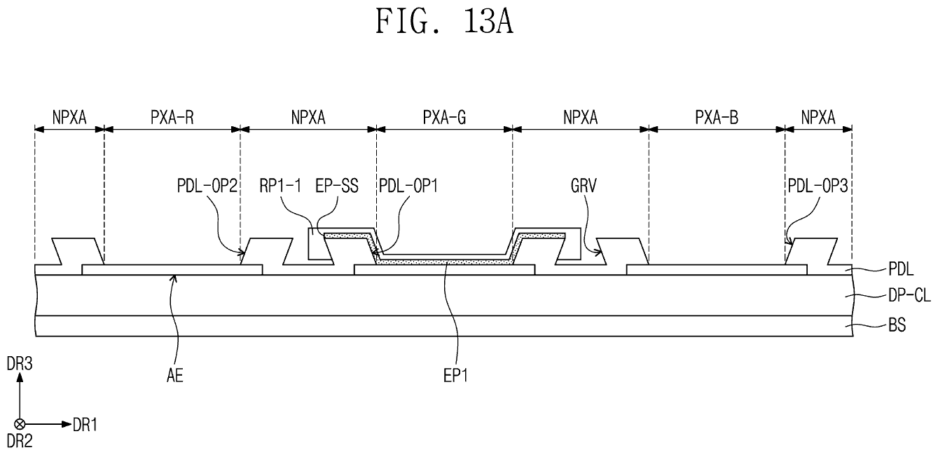

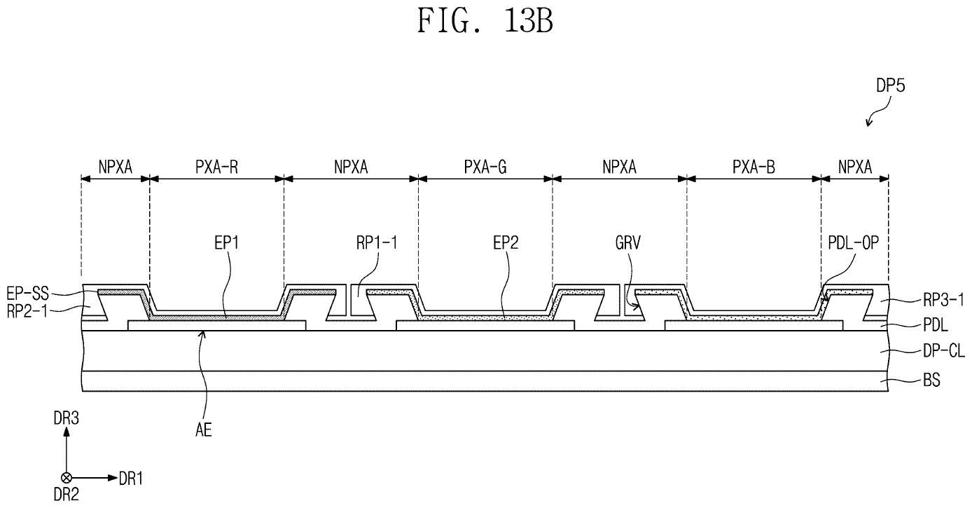

FIGS. 13A and 13B are cross-sectional views illustrating a method for manufacturing a display panel DP5 according to an embodiment of the invention. Hereinafter, with reference to FIGS. 13A and 13B, the same or similar reference numerals are used for the same or similar components described in FIGS. 5 to 12P, and redundant descriptions are omitted.

Referring to FIG. 13A, the first insulating layer RL1 may be patterned using the photoresist layer as a mask. The first insulating layer RL1 may be patterned to form the first preliminary insulating pattern RP1-1 (refer to FIG. 12F, for example). The first preliminary insulating pattern RP1-1 may be patterned into a shape which overlaps the first emission area PXA-G. The first insulating layer RL1 may be patterned through a dry etching process. However, this embodiment is not limited thereto.

Additionally, at least a portion of the first dummy light-emitting patterns DEP1 of the first emission layer EL1 may be removed using the PR pattern as a mask. At least a portion of first dummy light-emitting patterns DEP1 (see FIG. 12C) of the first emission layer EL1 may be removed to form the first light-emitting patterns EP1. The first light-emitting patterns EP1 may overlap the first emission area PXA-G.

Referring to FIGS. 13A and 13B, in the process of patterning or partially removing the first insulating layer RL1 and the first emission layer EL1, the first preliminary dummy pattern DPA1-1 (see FIG. 12E) may be removed together. That is, unlike the description referring to FIG. 12F, in an embodiment, the first preliminary dummy pattern DPA1-1 may be completely removed without being patterned. A bottom surface of the first preliminary insulating pattern RP1-1 within the groove GRV may be spaced apart by a gap (e.g., empty space) from a top surface of the pixel defining layer PDL which forms a bottom of the groove GRV. In this case, portions of the first insulating layer RL1 and patterns of the first emission layer EL1 may be removed through a wet etching process. However, this embodiment is not limited thereto.

Similarly, in the process of patterning or partially removing the second insulating layer RL2 (see FIG. 12H) and the second emission layer EL2 (see FIG. 12H), as well as in the process of patterning or partially removing the third insulating layer and the third emission layer, the preliminary dummy patterns may be completely removed without being patterned. Here, bottom surfaces of the various preliminary insulating patterns within respective grooves may be spaced apart by a gap (e.g., empty space) from a top surface of the pixel defining layer PDL which forms the bottoms of the grooves. Since the dummy pattern is completely removed, potential defects caused by the remaining dummy patterns in the process may be reduced or prevented in case that the dummy patterns remain. Additionally, as no additional process is required to remove the dummy patterns, the overall process may be simplified.

According to the invention, in the display panel DP in which the light-emitting device LD is formed without using the metal mask, a light emission material layer forming the emission layer may be segmented and formed by grooves GRV defined in the pixel defining layer PDL, and an insulating pattern layer may be formed on the emission layer to cover the side surfaces of the segmented emission layer.

Even when the light emission material layer forming the emission layer is patterned during the process to form light-emitting patterns, the side surfaces of the light-emitting patterns may be covered by the insulating pattern layer, preventing exposure of the light-emitting patterns to the external atmosphere. As a result, the highly reliable electronic apparatus may be provided.

In an embodiment, an electronic apparatus includes a pixel defining layer PDL in which an emission opening PDL-OP and a groove GRV which is adjacent to the emission opening are defined, a light-emitting element LD including a first electrode AE facing a second electrode CE and a light-emitting pattern EP which is between the first and second electrodes and overlapping the emission opening, the light-emitting pattern EP including a side surface EP-SS corresponding to the groove of the pixel defining layer, and an insulating pattern RP which overlaps the pixel defining layer with the light-emitting pattern therebetween, the insulating pattern extending along the light-emitting pattern and into the groove to cover the side surface of the light-emitting pattern. Here, the second electrode CE may face the light-emitting pattern EP with the insulating pattern RP therebetween, such as at a location adjacent to the emission opening.

Within the groove, the insulating pattern which covers the side surface of the light-emitting pattern may contact the dummy pattern DPA. Here, the dummy pattern and the light-emitting pattern may be respective portions of a same material layer.

The emission opening may be provided in plural including a first emission opening PDL-OP1 and a second emission opening PDL-OP2 (or PDL-OP3), the groove GRV being between the first emission opening and the second emission opening. The light-emitting pattern is provided in plural including a first light-emitting pattern EP1 which overlaps the first emission opening and is configured to emit first-color light, and a second light-emitting pattern EP2 (or EP3) which overlaps the second emission opening and is configured to emit second-color light which is different from the first-color light. The dummy pattern is provided in plural including a first dummy pattern DPA1 in a same material layer as the first light-emitting pattern, and a second dummy pattern DPA2 (or DPA3) in a same material layer as the second light-emitting pattern. Here, the first dummy pattern and the second dummy pattern may both be in the groove.

The electronic apparatus ED according to embodiments of the present disclosure may be applied to various electronic devices. An electronic apparatus ED may further include a module or device having additional functions in addition to the display panel DP. Within the groove, the insulating pattern which covers the side surface of the light-emitting pattern further contacts the first dummy pattern and the second dummy pattern (see FIGS. 5 and 6 where insulating patter RP is continuously across the non-emission area NPAX to contact adjacent light-emitting patterns.

The first dummy pattern and the second dummy pattern may be spaced apart from each other with a gap therebetween (see FIGS. 8A and 8B, for example).

Although the present disclosure has been described with reference to the embodiments, it will be understood that various changes and modifications of the present disclosure may be made by one ordinary skilled in the art or one having ordinary knowledge in the art without departing from the spirit and technical field of the disclosure as hereinafter claimed. Hence, the technical scope of the invention shall be determined by the technical scope of the accompanying claims.

What is claimed is:

1. An electronic apparatus comprising:
a pixel defining layer in which an emission opening and a groove which is adjacent to the emission opening are defined;
a light-emitting element comprising:
a first electrode facing a second electrode; and
a light-emitting pattern between the first electrode and the second electrode and overlapping the emission opening, the light-emitting pattern comprising a side surface corresponding to the groove of the pixel defining layer; and
an insulating pattern which overlaps the pixel defining layer with the light-emitting pattern therebetween, the insulating pattern extending along the light-emitting pattern and into the groove to cover the side surface of the light-emitting pattern.

2. The electronic apparatus of claim 1, further comprising a dummy pattern which is spaced apart from the light-emitting pattern and in the groove,
wherein within the groove, the insulating pattern which covers the side surface of the light-emitting pattern contacts the dummy pattern.

3. The electronic apparatus of claim 2, wherein the dummy pattern and the light-emitting pattern are respective portions of a same material layer.

4. The electronic apparatus of claim 1, wherein the second electrode faces the light-emitting pattern with the insulating pattern therebetween.

5. The electronic apparatus of claim 2, wherein
the emission opening is provided in plural including a first emission opening and a second emission opening, the groove being between the first emission opening and the second emission opening;
the light-emitting pattern is provided in plural including:
a first light-emitting pattern which overlaps the first emission opening and is configured to emit first-color light; and
a second light-emitting pattern which overlaps the second emission opening and is configured to emit second-color light which is different from the first-color light;
the dummy pattern is provided in plural including:
a first dummy pattern in a same material layer as the first light-emitting pattern; and
a second dummy pattern in a same material layer as the second light-emitting pattern; and
the first dummy pattern and the second dummy pattern are in the groove.

6. The electronic apparatus of claim 5, wherein within the groove, the insulating pattern which covers the side surface of the light-emitting pattern further contacts the first dummy pattern and the second dummy pattern.

7. The electronic apparatus of claim 5, wherein the first dummy pattern and the second dummy pattern are spaced apart from each other with a gap therebetween.

8. The electronic apparatus of claim 1, wherein
the pixel defining layer comprises an inner surface defining the groove, and
the insulating pattern contacts the inner surface of the pixel defining layer.

9. The electronic apparatus of claim 1, wherein the groove has a reverse-tapered shape in cross-section.

10. The electronic apparatus of claim 1, wherein the pixel defining layer comprises a tip portion which protrudes toward a center of the groove.

11. The electronic apparatus of claim 1, wherein
the pixel defining layer comprises an inner surface defining the groove, and
the inner surface comprises a curved portion in cross-section.

12. The electronic apparatus of claim 1, wherein the pixel defining layer is a single layer.

13. The electronic apparatus of claim 1, wherein
the pixel defining layer comprises:
a first pixel defining layer; and
a second pixel defining layer which on the first pixel defining layer, and
a material of the first pixel defining layer has an etching selectivity with respect to a material of the second pixel defining layer.

14. The electronic apparatus of claim 13, wherein
the material of the first pixel defining layer comprises silicon nitride, and
the material of the second pixel defining layer comprises silicon oxide.

15. The electronic apparatus of claim 13, wherein
the material of the first pixel defining layer comprises an organic material, and
the material of the second pixel defining layer comprises an inorganic material.

16. A method for manufacturing an electronic apparatus, the method comprising:
providing first electrodes on a base layer;
providing a pixel defining layer, in which a plurality of emission openings that overlap at least a portion of each of the first electrodes, and a groove that is spaced apart from the emission openings and is defined between the emission openings, are defined;
providing a first emission material layer on the pixel defining layer to form first light-emitting patterns, which overlap first emission openings of the emission openings, and first dummy light-emitting patterns, which overlap the rest of the emission openings of the emission openings;
providing a first insulating material layer configured to cover a top surface and a side surface of each of the first light-emitting patterns;
providing a first photoresist layer, which overlaps the first emission openings, on the first insulating material layer;
patterning the first insulating material layer to form a first preliminary insulating pattern;
removing at least a portion of the first dummy light-emitting pattern of the first emission material layer to form a first light-emitting pattern;
providing a second emission material layer on the pixel defining layer to form second light-emitting patterns, which overlap second emission openings of the emission openings, and second dummy light-emitting patterns, which overlap the rest of the emission openings of the emission openings, on the first light-emitting pattern and the first preliminary insulating layer;
providing a second insulating material layer configured to cover a top surface of a side surface of each of second light-emitting patterns;
providing a second photoresist layer, which overlaps the second emission openings, on the second insulating material layer;
patterning the second insulating material layer to form a second preliminary insulating pattern;
removing at least a portion of the second dummy light-emitting pattern of the second emission material layer to form a second light-emitting pattern;
providing a third photoresist layer on the first and second preliminary insulating patterns;
patterning the first and second preliminary insulating patterns to form an insulating pattern; and
providing a second electrode on the light-emitting pattern and the insulating pattern,
wherein the first and second photoresist layer partially overlap the groove, and
the third photoresist layer overlaps the groove and is spaced apart from the emission openings.

17. The method of claim 16, wherein the providing of the first emission material layer further comprises providing a first preliminary dummy pattern, which is separated from the first light-emitting patterns and the first dummy light-emitting patterns, in the groove,
wherein the first preliminary dummy pattern is patterned together during the patterning of the first insulating material layer to form a first dummy pattern,
wherein the providing of the second emission material layer further comprises providing a second preliminary dummy pattern, which is separated from the second light-emitting pattern and the second dummy light-emitting patterns, in the groove,
wherein the second preliminary dummy pattern is patterned together during the patterning of the second insulating material layer to form a second dummy pattern.

18. The method of claim 16, wherein the first insulating material layer is a continuous layer which is in contact with each the first light-emitting pattern and the first dummy light-emitting pattern.

19. The method of claim 16, wherein the providing of the pixel defining layer comprises:
providing a first pixel defining material layer;
providing a second pixel defining material layer on the first pixel defining material layer;
etching the first and second pixel defining material layers using an etching gas to provide the first and second emission openings and the groove; and
the providing of the groove comprising an etching rate of the etching gas with respect to the first pixel defining material layer being greater than an etching rate of the etching gas with respect to the second pixel defining material layer.

20. The method of claim 16, wherein each of the patterning of the first insulating material layer and the patterning of the second insulating material layer comprises dry etching.
